(19) United States
(12) Patent Application Publication
(10) Pub. No.: US 2026/0248049 A1
(43) Pub. Date: Aug. 20, 2026

(54) WIRING SUBSTRATE AND SEMICONDUCTOR DEVICE

(71) Applicant: Shinko Electric Industries Co., LTD., Nagano-Shi (JP)

(72) Inventors: Shuhei Momose, Nagano-Shi (JP); Kenta Nakamura, Nagano-Shi (JP)

(73) Assignee: Shinko Electric Industries Co., LTD., Nagano-Shi (JP)

(21) Appl. No.: 19/535,001

(22) Filed: Feb. 10, 2026

(30) Foreign Application Priority Data
Feb. 14, 2025 (JP) 2025-022224

(51) Int. Cl. H10W 90/00; H10W 70/05; H10W 70/60; H10W 70/68; H10W 90/10; H10W 90/22

(52) U.S. Cl. CPC H10W 90/401; H10W 70/618; H10W 70/682; H10W 90/22; H10W 70/095; H10W 90/10

(57) ABSTRACT

A wiring substrate of a coreless type includes a first wiring layer and an N number of insulating layers, including a first insulating layer that covers the first wiring layer, where N is a natural number greater than or equal to 1. A cavity extends through the N number of insulating layers in a thickness direction. A first electronic component, disposed in the cavity, includes a first electrode. A capping insulating layer fills the cavity and covers the first electronic component. The first wiring layer does not overlap the cavity in plan view. The first wiring layer includes a first mounting surface exposed from the first insulating layer. The first electrode includes a second mounting surface exposed from the capping insulating layer. The second mounting surface is coplanar with the first mounting surface.

### CROSS-REFERENCE TO RELATED APPLICATIONS

This application is based upon and claims the benefit of priority from prior Japanese Patent Application No. 2025-022224, filed on Feb. 14, 2025, the entire contents of which are incorporated herein by reference.

### BACKGROUND

### 1. Field

This disclosure relates to a wiring substrate, a semiconductor device, and a method for manufacturing a wiring substrate.

### 2. Description of Related Art

JP2024-124330A describes electronic components such as semiconductor chips mounted on a wiring substrate. The wiring substrate incorporates circuit elements that are electrically connected to the electronic components. In such type of a wiring substrate, a circuit element such as a chip capacitor is disposed in a cavity formed in an insulating layer, and the cavity is filled with a capping insulating layer that covers the circuit component. Further, the wiring substrate includes a conductive pad and an electrode pad. The conductive pad is included in the uppermost wiring layer and projects upward beyond an upper surface of the uppermost insulating layer. The electrode pad is formed on the upper surface of the circuit element at a lower position than the upper surface of the uppermost insulating layer. An electronic component is disposed on the conductive pad and the electrode pad so as to overlie the conductive pad and the electrode pad.

### SUMMARY

It is desirable that such a wiring substrate allow for facilitated mounting of electronic components.

In one general aspect, a wiring substrate is of a coreless type. The wiring substrate includes a first wiring layer, an N number of insulating layers, including a first insulating layer that covers the first wiring layer, where N is a natural number greater than or equal to 1, a cavity extending through the N number of insulating layers, a first electronic component disposed in the cavity and including a first electrode, and a capping insulating layer filling the cavity and covering the first electronic component. The first wiring layer does not overlap the cavity in plan view. The first wiring layer includes a first mounting surface exposed from the first insulating layer. The first electrode includes a second mounting surface exposed from the capping insulating layer. The second mounting surface is coplanar with the first mounting surface.

Other features and aspects will be apparent from the following detailed description, the drawings, and the claims.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 is a cross-sectional view of a wiring substrate in accordance with a first embodiment.

FIG. 2 is a partially enlarged cross-sectional view of the wiring substrate illustrated in FIG. 1.

FIG. 3 is a cross-sectional view of a semiconductor device including the wiring substrate of FIG. 1.

FIGS. 4, 5, 6, 7, 8, 9, 10, 11, 12, 13, 14, 15, 16, 17, 18, 19, 20, 21, 22, 23, 24, and 25 are cross-sectional views illustrating a method for manufacturing the wiring substrate of FIG. 1.

FIG. 26 is a cross-sectional view of a wiring substrate in accordance with a second embodiment.

FIG. 27 is a partially enlarged cross-sectional view of the wiring substrate illustrated in FIG. 26.

FIGS. 28, 29, 30, 31, 32, 33, 34, 35, 36, 37, and 38 are cross-sectional views illustrating a method for manufacturing the wiring substrate of FIG. 26.

FIG. 39 is a cross-sectional view of an exemplary application of the wiring substrate illustrated in FIG. 26.

FIG. 40 is a cross-sectional view of a wiring substrate in accordance with a third embodiment.

FIG. 41 is a partially enlarged cross-sectional view of the wiring substrate illustrated in FIG. 40.

FIGS. 42, 43, 44, 45, 46, 47, 48, 49, 50, 51, and 52 are cross-sectional views illustrating a method for manufacturing the wiring substrate of FIG. 40.

FIG. 53 is a cross-sectional view of an exemplary application of the wiring substrate illustrated in FIG. 40.

FIG. 54 is a cross-sectional view illustrating a modified example of the wiring substrate.

FIG. 55 is a partially enlarged cross-sectional view of the wiring substrate illustrated in FIG. 54.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

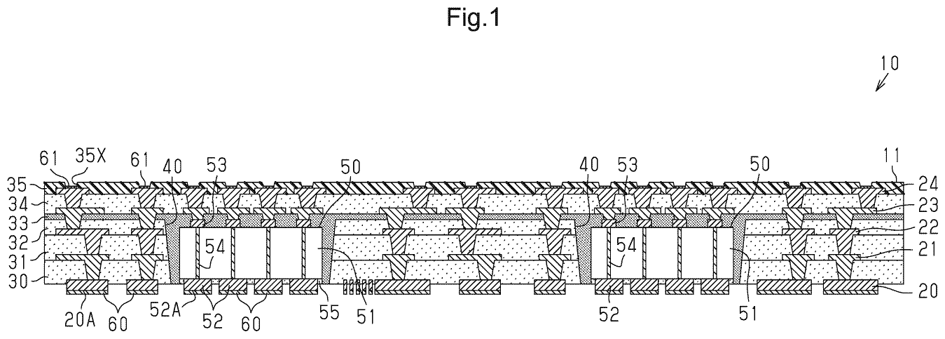

Embodiments will now be described with reference to the drawings. In the accompanying drawings, elements are illustrated for simplicity and clarity and have not necessarily been drawn to scale. To facilitate understanding, hatching lines may be replaced by shadings or may not be illustrated in the cross-sectional views. In this specification, a “plan view” refers to a view of a subject as seen in the vertical direction in FIG. 1. A “planar shape” refers to a shape of a subject as seen in the vertical direction in FIG. 1. In this specification, upward, downward, leftward, and rightward directions refer to directions that allow for the reference characters denoting members to be read properly. Further, unless otherwise specified, a numerical range of “X1 to X2,” which is specified by upper limit value X1 and lower limit value X2, refers to a range that is greater than or equal to X1 and less than or equal to X2. Also, in this specification, the term “face” is used to indicate that surfaces or members are arranged in front of each other. In this case, the surfaces or members do not have to be entirely in front of each other and may be partially in front of each other. Moreover, in this specification, the term “face” will also be used to describe situations including a case in which two members are separated from each other and a case in which two members are in contact with each other.

### First Embodiment

A first embodiment will now be described with reference to FIGS. 1 to 25.

### Overall Structure of Wiring Substrate 10

As illustrated in FIG. 1, a wiring substrate 10 includes a wiring structure 11, one or more (two in the first embodiment) cavities 40 formed in the wiring structure 11, and one or more (two in the first embodiment) electronic components 50 disposed in the cavities 40. The wiring substrate 10 incorporates the electronic components 50. The directions in the drawings do not necessarily indicate the orientation of the wiring substrate 10 in actual use.

### The Wiring Structure 11

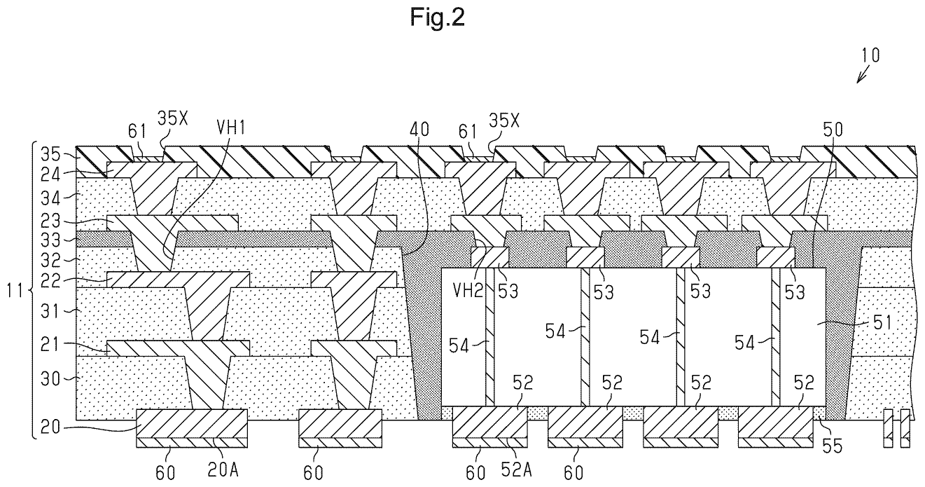

As illustrated in FIG. 2, the wiring structure 11 is a stack of a wiring layer 20, an insulating layer 30, a wiring layer 21, an insulating layer 31, a wiring layer 22, an insulating layer 32, an insulating layer 33, a wiring layer 23, an insulating layer 34, a wiring layer 24, and a solder resist layer 35. The wiring substrate 10 of the first embodiment is a coreless substrate that does not include a support base.

The material of the wiring layers 20, 21, 22, 23, and 24 may be, for example, copper or a copper alloy. The wiring layers 20, 21, 22, 23, and 24 each have a thickness of, for example, approximately 1 μm to 35 μm.

The insulating layers 30, 31, 32, 33, and 34 may be formed from, for example, a material of which the main component is a non-photosensitive resin. The insulating layers 30, 31, 32, 33, and 34 may be formed from, for example, a material of which the main component is a thermosetting, non-photosensitive resin, such as an epoxy resin, an imide resin, a phenol resin, or a cyanate resin. The solder resist layer 35 may be formed from, for example, a material of which the main component is a photosensitive resin. The solder resist layer 35 may be formed from, for example, a photosensitive insulative resin of which the main component is a phenol resin or a polyimide resin.

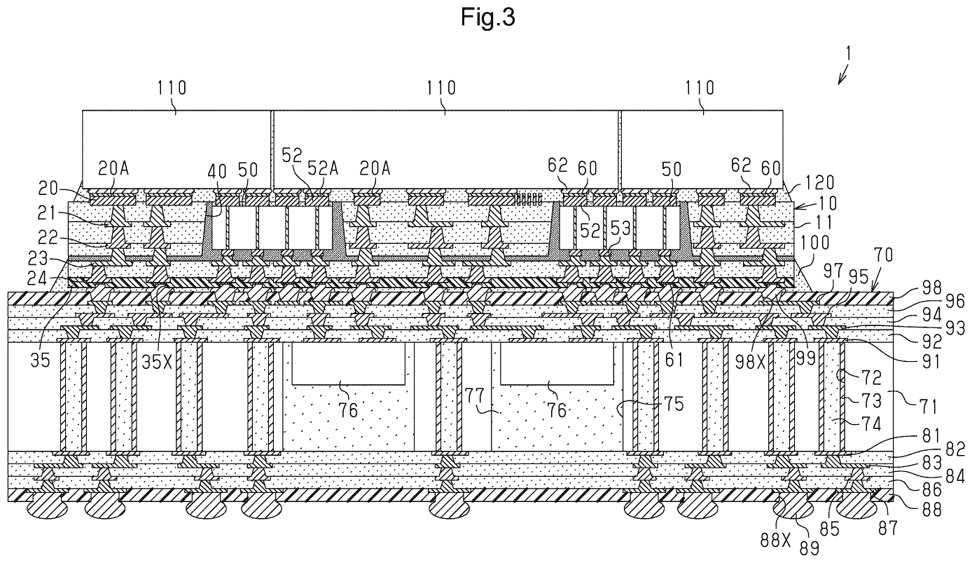

The wiring layer 20 projects beyond a lower surface (third surface) of the insulating layer 30 in a downward direction (first direction). A part of the wiring layer 20, namely, the upper portion of the wiring layer 20, is embedded in the insulating layer 30. The wiring layer 20 does not overlap the cavities 40 in plan view. In other words, the wiring layer 20 is separated from the cavities 40 in plan view. The wiring layer 20 is, for example, the outermost layer (here, the lowermost layer) of the wiring substrate 10. The wiring layer 20 has, for example, the functionality of a chip mounting pad electrically connected to electronic components, such as semiconductor chips 110 (refer to FIG. 3). The wiring layer 20 includes a mounting surface 20A (lower surface in FIG. 2) on which the electronic components, such as the semiconductor chips 110 are mounted. The mounting surface 20A of the wiring layer 20 is located toward the first direction from the lower surface of the insulating layer 30. The projection amount of the wiring layer 20 from the lower surface of the insulating layer 30, that is, the thickness of the mounting surface 20A from the lower surface of the insulating layer 30 is, for example, approximately 5 μm to 10 μm.

A surface-processed layer 60 may be formed on the surface (mounting surface 20A and side surfaces, or only mounting surface 20A) of the wiring layer 20, when required. The surface-processed layer 60 of the first embodiment covers only the mounting surface 20A of the wiring layer 20. The surface-processed layer 60 may be a gold (Au) layer, a nickel (Ni) layer/Au layer (metal layer formed by laminating a Ni layer and a Au layer in this order), or a Ni layer/palladium (Pd) layer/Au layer (metal layer formed by laminating a Ni layer, a Pd layer, and a Au layer in this order). Further, the surface-processed layer 60 may be a Ni layer/tin (Sn) layer (metal layer formed by laminating a Ni layer and a Sn layer in this order), Ni layer/Sn layer/indium (In) layer (metal layer formed by laminating a Ni layer, a Sn layer, and an In layer in this order), a bismuth (Bi) layer, or the like. A Au layer is a metal layer formed from Au or an Au alloy, a Ni layer is a metal layer formed from Ni or a Ni alloy, and a Pd layer is a metal layer formed from Pd or a Pd alloy. Further, a Sn layer is a metal layer formed from Sn or a Sn alloy, an In layer is a metal layer formed from In or an In alloy, and a Bi layer is a metal layer formed from Bi or a Bi alloy. The Au layer, the Ni layer, the Pd layer, the Sn layer, the In layer, and the Bi layer may each be, for example, a metal layer formed through an electroless plating process (electroless plating metal layer) or a metal layer formed through an electrolytic plating process (electrolytic plating metal layer). The surface-processed layer 60 may be an organic solderability preservative (OSP) film formed on the surface of the wiring layer 20 through an anti-oxidation process such as an OSP process. The OSP film may be, for example, an organic coating of an azole compound or an imidazole compound.

The insulating layer 30 covers the upper surface of the wiring layer 20. The insulating layer 30 covers a part of each side surface of the wiring layer 20 and exposes the remaining part of the side surface of the wiring layer 20. The insulating layer 30 covers the upper portion of the side surface of the wiring layer 20. The insulating layer 30 is, for example, the outermost (here, the lowermost) insulating layer of the wiring substrate 10. The thickness from the upper surface of the wiring layer 20 to the upper surface of the insulating layer 30 is, for example, approximately 15 μm to 60 μm.

The wiring layer 21 is formed on the upper surface of the insulating layer 30. The wiring layer 21 is electrically connected to the wiring layer 20 by via wiring extending through the insulating layer 30 in the thickness direction. The wiring layer 21 does not overlap the cavities 40 in plan view. In other words, the wiring layer 21 is separated from the cavities 40 in plan view.

The insulating layer 31 is formed on the upper surface of the insulating layer 30 and covers the wiring layer 21. The insulating layer 31 covers the upper surface and the side surfaces of the wiring layer 21. The thickness from the upper surface of the wiring layer 21 to the upper surface of the insulating layer 31 is, for example, approximately 15 μm to 60 μm.

The wiring layer 22 is formed on the upper surface of the insulating layer 31. The wiring layer 22 is electrically connected to the wiring layer 21 by via wiring extending through the insulating layer 31 in the thickness direction. The wiring layer 22 does not overlap the cavities 40 in plan view. In other words, the wiring layer 22 is separated from the cavities 40 in plan view.

The insulating layer 32 is formed on the upper surface of the insulating layer 31 and covers the wiring layer 22. The insulating layer 32 covers the upper surface and the side surfaces of the wiring layer 22. The thickness from the upper surface of the wiring layer 22 to the upper surface of the insulating layer 32 is, for example, approximately 10 μm to 40 μm.

The cavities 40 are formed in the insulating layers 30, 31, and 32. The cavities 40 are recessed downward from the upper surface of the insulating layer 32. The cavities 40 extend through the insulating layers 30, 31, and 32 in the thickness direction. The cavities 40 are formed in correspondence with the incorporated electronic components 50. That is, each cavity 40 is formed at a position where one of the electronic components 50 is disposed.

The cavities 40 are each, for example, tapered so that its opening width decreases from the upper side (upper surface of insulating layer 32) toward the lower side (lower surface of insulating layer 30), as viewed in FIG. 2. That is, the cavities 40 widen from the lower side toward the upper side. The space inside each cavity 40 is used to accommodate the corresponding electronic component 50. In the wiring substrate 10 of the first embodiment, the three insulating layers 30, 31, and 32 define a cavity-formation insulating layer.

### Structure of the Electronic Component 50

Each electronic component 50 includes a main body 51, a first electrode 52 arranged on the lower portion of the electronic component 50, a second electrode 53 arranged on the upper portion of the electronic component 50, and a through-electrode 54. The electronic component 50 includes, for example, an insulating resin 55. In the first embodiment, the electronic component 50 includes multiple first electrodes 52, multiple second electrodes 53, and multiple through-electrodes 54.

The electronic component 50 may be, for example, a semiconductor element, a quartz oscillator, a chip component, or a silicon bridge. Examples of a chip component include a chip capacitor, a chip resistor, and a chip inductor. The electronic components 50 incorporated in the wiring substrate 10 do not have to be of a single type and may be of plural types.

The main body 51 is, for example, box-shaped. The main body 51 may have a thickness of, for example, approximately 50 μm to 200 μm. The main body 51 is formed from, for example, silicon (Si) or silicon carbide (SiC).

The material of the first electrodes 52, the second electrodes 53 and the through-electrodes 54 may be, for example, a metal such as aluminum (Al) or copper (Cu) or an alloy including at least one of these metals.

The first electrodes 52 project, for example, from the lower surface (first surface) of the main body 51 in the downward direction (first direction). The first electrodes 52 project, for example, beyond the lower surface (second surface) of the insulating resin 55 in the downward direction (first direction). The first electrodes 52 project, for example, downward beyond the lower surface of the insulating layer 30. A part of each first electrode 52, namely, the upper portion of each first electrode 52, is embedded in the insulating resin 55. The first electrodes 52 have, for example, the functionality of chip mounting pads electrically connected to electronic components, such as the semiconductor chips 110 (refer to FIG. 3). The first electrodes 52 each include a mounting surface 52A (lower surface in FIG. 2) on which an electronic component, such as the semiconductor chip 110, is mounted. The mounting surface 52A of each first electrode 52 is coplanar with the mounting surface 20A of the wiring layer 20. The first electrodes 52 may each have a thickness of, for example, approximately 2 μm to 20 μm. A part of each first electrode 52 may be embedded in the main body 51.

The surface-processed layer 60 is formed on the surface (mounting surface 52A and side surfaces, or only mounting surface 52A) of each first electrode 52, when required. The surface-processed layer 60 of the first embodiment covers only the mounting surface 52A of each first electrode 52. The surface-processed layer 60 formed on the mounting surface 52A has the same thickness as the surface-processed layer 60 formed on the mounting surface 20A. Thus, the lower surface of the surface-processed layer 60 formed on the mounting surface 52A is coplanar with the lower surface of the surface-processed layer 60 formed on the mounting surface 20A.

The insulating resin 55 is formed on the lower surface of the main body 51. The insulating resin 55 covers, for example, the entire lower surface of the main body 51 exposed between the first electrodes 52. The insulating resin 55 covers a part of the side surface of each first electrode 52 and exposes the remaining part of the side surface of the first electrode 52. The insulating resin 55 covers the upper portion of the side surface of each first electrode 52. The lower surface of the insulating resin 55 is, for example, coplanar with the lower surface of the insulating layer 30.

The insulating resin 55 is, for example, an insulating layer of which the main component is a non-photosensitive resin. The insulating resin 55 may be, for example, a material of which the main component is a thermosetting, non-photosensitive resin, such as an epoxy resin, an imide resin, a phenol resin, or a cyanate resin. The insulating resin 55 may be, for example, an adhesive agent in which a filler is mixed in a base resin, such as an epoxy resin.

The second electrodes 53 are arranged on the main body 51 at the opposite side of the first electrodes 52. The second electrodes 53 project, for example, upward from the upper surface of the main body 51. The second electrodes 53 may each have a thickness of, for example, approximately 2 μm to 20 μm. The second electrodes 53 may be embedded in the main body 51.

The through-electrodes 54 extend through the main body 51 in the thickness direction. The through-electrodes 54, for example, extend straight in the thickness direction of the main body 51. The through-electrodes 54 electrically connect the first electrodes 52 to the second electrodes 53.

The insulating layer 33 acts as a capping insulating layer that caps the cavities 40. The insulating layer 33 caps the cavities 40 and covers the electronic component 50. The insulating layer 33 covers the wall surface of each cavity 40. The insulating layer 33, for example, entirely covers the electronic component 50. The insulating layer 33, for example, entirely covers the side surfaces of the insulating resin 55. The insulating layer 33 covers, for example, the upper surface and the side surface of the main body 51. The insulating layer 33 covers, for example, the upper surface and the side surface of each second electrode 53.

The lower surface of the parts of the insulating layer 33 in the cavities 40 are, for example, exposed from the lower surface of the insulating layer 30 and the lower surface of the insulating resin 55. The lower surface of the parts of the insulating layer 33 in the cavities 40 are, for example, flush with the lower surface of the insulating layer 30 and the lower surface of the insulating resin 55.

The insulating layer 33 covers the upper surface of the insulating layer 32. The insulating layer 33 covers, for example, the entire upper surface of the insulating layer 32.

Through holes VH1 extend through the insulating layers 32 and 33 in the thickness direction of the insulating layers 32 and 33 at given locations and expose parts of the upper surface of the wiring layer 22. Through holes VH2 extend through the insulating layer 33 in the thickness direction of the insulating layer 33 at given locations and expose parts of the upper surface of each second electrode 53. The through holes VH1 and VH2 are each, for example, tapered so that its diameter (opening width) decreases downward from the upper side (upper surface of insulating layer 33) toward the lower side as viewed in FIG. 2. The through holes VH1 and VH2 each have, for example, the form of a truncated cone so that the diameter at the lower end is smaller than the diameter at the upper end. The thickness from the upper surface of the insulating layer 32 to the upper surface of the insulating layer 33 may be, for example, approximately 5 μm to 30 μm.

The wiring layer 23 is formed on the upper surface of the insulating layer 33. The wiring layer 23 is, for example, electrically connected to the wiring layer 22 by the via wiring in the through holes VH1. The wiring layer 23 is, for example, electrically connected to the second electrodes 53 by the via wiring in the through holes VH2. The wiring layer 23 is formed integrally with the via wiring in the through holes VH1 and the via wiring in the through holes VH2. The wiring layer 23 may be laid out on the upper surface of the insulating layer 33 in a planar direction, which is the direction orthogonal to the stacking direction of the wiring substrate 10. When the wiring layer 23 is laid out in such a manner, the part of the wiring layer 23 connected to the wiring layer 22 may be electrically connected to the part of the wiring layer 23 that is connected to the second electrodes 53.

The insulating layer 34 is formed on the insulating layer 33 and covers the wiring layer 23. The insulating layer 34 covers the upper surface and the side surfaces of the wiring layer 23. The thickness from the upper surface of the wiring layer 23 to the upper surface of the insulating layer 34 is, for example, approximately 15 μm to 60 μm.

The wiring layer 24 is formed on the upper surface of the insulating layer 34. The wiring layer 24 is electrically connected to the wiring layer 23 by via wiring extending through the insulating layer 34 in the thickness direction. The wiring layer 24 is, for example, the outermost (here, the uppermost) wiring layer of the wiring substrate 10.

The solder resist layer 35 is formed on the upper surface of the insulating layer 34 and covers the wiring layer 24. The solder resist layer 35 covers the upper surface and the side surfaces of the wiring layer 24. The solder resist layer 35 is the outermost (here, the uppermost) insulating layer of the wiring substrate 10. The thickness from the upper surface of the wiring layer 24 to the upper surface of the solder resist layer 35 may be, for example, approximately 12 μm to 50 μm.

The solder resist layer 35 includes openings 35X exposing parts of the upper surface of the uppermost wiring layer 24 as connection pads. The openings 35X are, for example, tapered and reduced in diameter (opening width) from the upper side (upper surface of solder resist layer 35) toward the lower side as viewed in FIG. 2. The openings 35X each have, for example, the form of a truncated cone so that the diameter at the lower end is smaller than the diameter at the upper end.

A surface-processed layer 61 is formed on the wiring layer 24 exposed from the openings 35X, when required. The surface-processed layer 61 may be an OSP film or a metal layer, such as a Au layer, a Ni layer/Au layer, a Ni layer/Pd layer/Au layer, a Ni layer/Sn layer, a Ni layer/Sn layer/In layer, or a Bi layer.

### Structure of Semiconductor Device 1

The structure of a semiconductor device 1 will now be described with reference to FIG. 3.

The semiconductor device 1 includes a substrate 70, the wiring substrate 10 mounted on the substrate 70, an underfill resin 100, one or more (three in the first embodiment) semiconductor chips 110 mounted on the wiring substrate 10, and an underfill resin 120. FIG. 3 illustrates the wiring substrate 10 in a state rotated 180° from the state of FIG. 1.

### Structure of the Substrate 70

The substrate 70 includes a core substrate 71. The core substrate 71 may be, for example, a glass epoxy substrate obtained by impregnating a glass cloth with a thermosetting insulative resin such as an epoxy resin. The core substrate 71 may be, for example, a substrate obtained by impregnating a woven cloth or non-woven cloth of glass fibers, carbon fibers, aramid fibers, or the like with a thermosetting insulative resin such as an epoxy resin. The drawings do not illustrate the glass cloth or the like.

The core substrate 71 includes through holes 72 extending through the core substrate 71 in the thickness direction. A through-electrode 73 extending through the core substrate 71 in the thickness direction is formed on the wall surface of each through hole 72. The central portion of each through hole 72, that is, the inner side of the through-electrode 73 in each through hole 72, is filled with a resin portion 74. The material of the through-electrode 73 may be, for example, copper or a copper alloy. The material of the resin portion 74 may be, for example, an insulative resin such as an epoxy resin.

The core substrate 71 includes one or more (two in the first embodiment) openings 75 extending through the core substrate 71 in the thickness direction. An electronic component 76 is accommodated in each opening 75. Each opening 75 is filled with a resin portion 77 that covers the corresponding electronic component 76. The resin portion 77 covers, for example, the lower surface and side surfaces of the electronic component 76. The electronic component 76 may be, for example, a semiconductor element, a quartz oscillator, a chip component, or a silicon bridge. Examples of a chip component include a chip capacitor, a chip resistor, and a chip inductor. The electronic components 76 incorporated in the substrate 70 do not have to be of a single type and may be of two or more types. The material of the resin portion 77 may be, for example, an insulative resin such as an epoxy resin.

The substrate 70 includes a wiring structure formed by sequentially stacking a wiring layer 81, an insulating layer 82, a wiring layer 83, an insulating layer 84, a wiring layer 85, an insulating layer 86, a wiring layer 87, and a solder resist layer 88 on the lower surface of the core substrate 71. The substrate 70 also includes a wiring structure formed by sequentially stacking a wiring layer 91, an insulating layer 92, a wiring layer 93, an insulating layer 94, a wiring layer 95, an insulating layer 96, a wiring layer 97, and a solder resist layer 98 on the upper surface of the core substrate 71.

The material of the wiring layers 81, 83, 85, 87, 91, 93, 95, and 97 may be, for example, copper or a copper alloy. The wiring layers 81, 83, 85, 87, 91, 93, 95, and 97 may each have a thickness of, for example, approximately 8 μm to 40 μm. The insulating layers 82, 84, 86, 92, 94, and 96 may be formed from, for example, a material of which the main component is a non-photosensitive resin. The insulating layers 82, 84, 86, 92, 94, and 96 may be formed from, for example, a material of which the main component is a thermosetting, non-photosensitive resin, such as an epoxy resin, an imide resin, a phenol resin, or a cyanate resin. The insulating layers 82, 84, 86, 92, 94, and 96 may each have a thickness of, for example, approximately 15 μm to 100 μm. The solder resist layers 88 and 98 may be formed from a material of which the main component is a photosensitive resin. The solder resist layers 88 and 98 may be formed from, for example, a photosensitive insulative resin of which the main component is a phenol resin or a polyimide resin. The solder resist layers 88 and 98 may each have a thickness of, for example, approximately 12 μm to 50 μm.

The wiring layer 81 is formed on the lower surface of the core substrate 71. The wiring layer 81 is electrically connected to the through-electrodes 73. The insulating layer 82 is formed on the lower surface of the core substrate 71 and covers the wiring layer 81. The wiring layer 83 is formed on the lower surface of the insulating layer 82. The wiring layer 83 is electrically connected to the wiring layer 81 by via wiring extending through the insulating layer 82 in the thickness direction. The insulating layer 84 is formed on the lower surface of the insulating layer 82 and covers the wiring layer 83. The wiring layer 85 is formed on the lower surface of the insulating layer 84. The wiring layer 85 is electrically connected to the wiring layer 83 by via wiring extending through the insulating layer 84 in the thickness direction. The insulating layer 86 is formed on the lower surface of the insulating layer 84 and covers the wiring layer 85. The wiring layer 87 is formed on the lower surface of the insulating layer 86. The wiring layer 87 is electrically connected to the wiring layer 85 by via wiring extending through the insulating layer 86 in the thickness direction.

The solder resist layer 88 is formed on the lower surface of the insulating layer 86 and covers the wiring layer 87. The solder resist layer 88 includes openings 88X exposing parts of the lower surface of the lowermost wiring layer 87 as external connection pads. External connection terminals 89 are disposed on the lower surface of the wiring layer 87 exposed from the openings 88X. The external connection terminals 89 may be, for example, solder balls.

The wiring layer 91 is formed on the upper surface of the core substrate 71. The wiring layer 91 is electrically connected to the wiring layer 81 by the through-electrodes 73. Parts of the wiring layer 91 are electrically connected to the electronic components 76. The insulating layer 92 is formed on the upper surface of the core substrate 71 and covers the wiring layer 91. The wiring layer 93 is formed on the upper surface of the insulating layer 92. The wiring layer 93 is electrically connected to the wiring layer 91 by via wiring extending through the insulating layer 92 in the thickness direction. The insulating layer 94 is formed on the upper surface of the insulating layer 92 and covers the wiring layer 93. The wiring layer 95 is formed on the upper surface of the insulating layer 94. The wiring layer 95 is electrically connected to the wiring layer 93 by via wiring extending through the insulating layer 94 in the thickness direction. The insulating layer 96 is formed on the upper surface of the insulating layer 94 and covers the wiring layer 95. The wiring layer 97 is formed on the upper surface of the insulating layer 96. The wiring layer 97 is electrically connected to the wiring layer 95 by via wiring extending through the insulating layer 96 in the thickness direction.

The solder resist layer 98 is formed on the upper surface of the insulating layer 96 and covers the wiring layer 97. The solder resist layer 98 includes openings 98X exposing parts of the upper surface of the uppermost wiring layer 97 as connection pads. The openings 98X overlap the openings 35X in the solder resist layer 35 of the wiring substrate 10 in plan view.

### Structure of the Wiring Substrate 10

The wiring substrate 10 is mounted on the upper surface of the substrate 70. The wiring substrate 10 is mounted on the upper surface of the substrate 70 with the wiring layer 24 and the solder resist layer 35 facing the upper surface of the substrate 70. The wiring layer 24, which is exposed from the openings 35X in the solder resist layer 35, is bonded to the wiring layer 97, which is exposed from the openings 98X in the solder resist layer 98, by bonding members 99. The bonding members 99 bond the wiring layer 24 (i.e., surface-processed layer 61), exposed from the openings 35X, to the wiring layer 97, exposed from the openings 98X. The bonding members 99 may be, for example, a solder layer. The material of the solder layer may be, for example, Pb-free solder of Sn—Ag, Sn—Cu, or Sn—Ag—Cu. The bonding members 99 may be, for example, a Cu—Ni—Sn electrolytic plating metal layer or a copper ink paste.

In this manner, the substrate 70 and the wiring substrate 10 are bonded by the bonding members 99 to form the semiconductor device 1 having a Package on Package (POP) configuration. The electronic components 76 incorporated in the substrate 70 may be electrically connected to the electronic components 50 incorporated in the wiring substrate 10 by the wiring layers 91, 93, 95, 97, 24, 23, and the like.

### Structure of the Underfill Resin 100

The gap between the substrate 70 and the wiring substrate 10 is filled with the underfill resin 100. For example, the gap between the solder resist layer 98 and the solder resist layer 35 is filled with the underfill resin 100. The material of the underfill resin 100 may be, for example, an insulative resin such as an epoxy resin.

### Structure of the Semiconductor Chip 110

Each semiconductor chip 110 is flip-chip mounted on the wiring layer 20 and the first electrodes 52 of the wiring substrate 10. Each semiconductor chip 110 is electrically connected to the wiring layer 20 and the first electrodes 52 by bonding members 62 and the surface-processed layer 60. Each semiconductor chip 110 mounted on the wiring substrate 10 overlies the wiring layer 20 and the first electrodes 52. The bonding members 62 are bonded to the surface-processed layer 60, which is formed on the wiring layer 20. The bonding members 62 may be, for example, a solder layer. The material of the solder layer may be, for example, Pb-free solder of Sn—Ag, Sn—Cu, or Sn—Ag—Cu.

The semiconductor chips 110 may include, for example, a logic chip such as a central processing unit (CPU) chip or a graphics processing unit (GPU) chip. Further, the semiconductor chips 110 may include, for example, a memory chip such as a dynamic random-access memory (DRAM) chip, a static random-access memory (SRAM) chip, or a flash memory chip. When mounting the semiconductor chips 110 on the wiring substrate 10, a logic chip may be mounted in combination with a memory chip on the wiring substrate 10.

### Structure of the Underfill Resin 120

The gaps between the wiring substrate 10 and the semiconductor chips 110 are filled with the underfill resin 120. For example, the gaps between the semiconductor chips 110 are filled with the underfill resin 120. The material of the underfill resin 120 may be, for example, an insulative resin such as an epoxy resin.

### Method for Manufacturing the Wiring Substrate 10

A method for manufacturing the wiring substrate 10 will now be described. To simplify illustration, elements that will consequently become final elements of the wiring substrate 10 are given the same reference characters as the final elements.

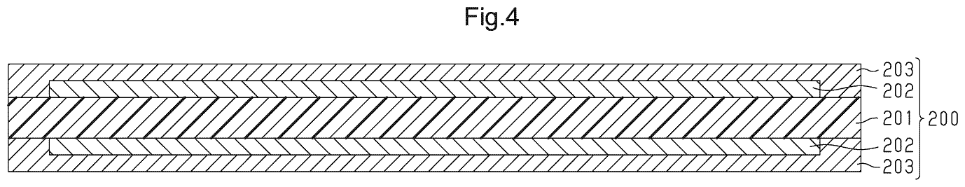

In the step illustrated in FIG. 4, a support 200 is prepared. The support 200 is constructed by, for example, sequentially stacking a metal film 202 and a metal film 203 on both upper and lower surfaces of a base 201. The base 201 is formed from, for example, a prepreg obtained by impregnating a reinforcement material such as a woven or non-woven cloth of glass fibers, aramid fibers, or liquid crystal polymer (LCP) fibers with a thermosetting insulative resin, such as an epoxy resin or a polyimide resin. Each metal film 202 is, for example, a Cu film. Each metal film 203 covers the side surfaces of the corresponding metal film 202. The metal film 203 covers the corresponding upper or lower surface of the base 201 exposed from the metal film 202. Each metal film 203 is, for example, a Cu plating film. The material of the metal film 202 is not limited to copper and may be a metal other than copper. The material of the metal film 203 is not limited to copper and may be a metal other than copper.

In the manufacturing method in accordance with the first embodiment, a structure corresponding to part of the wiring substrate 10 is formed on both upper and lower surfaces of the support 200. For the sake of brevity, the description illustrates only the structure formed on the upper surface of the support 200.

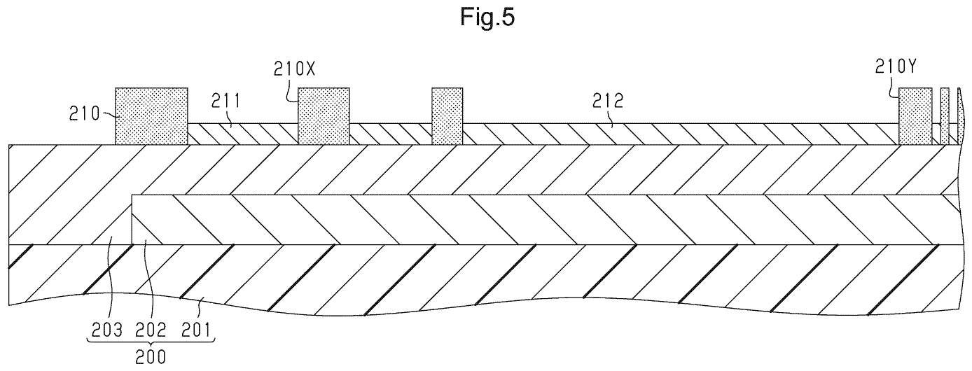

In the step illustrated in FIG. 5, a resist layer 210 including opening patterns 210X and 210Y is formed on the upper surface of the metal film 203 of the support 200. The opening pattern 210X exposes parts in the upper surface of the metal film 203 that correspond to regions where the wiring layer 20, illustrated in FIG. 2, is formed. The opening pattern 210Y exposes parts in the upper surface of the metal film 203 that correspond to regions where the electronic components 50, illustrated in FIG. 2, are mounted. The material of the resist layer 210 may be, for example, a material that resists plating in the plating process performed in the following step. The material of the resist layer 210 may be, for example, a photosensitive dry film resist or a liquid photoresist (e.g., dry film resist or liquid resist of novolac resin or acrylic resin). When using a photosensitive dry film, thermal compression bonding is performed to laminate a dry film onto the upper surface of the metal film 203, and a photolithography process is performed to pattern the dry film and form the resist layer 210 including the opening pattern 210X. When using a liquid photoresist, the resist layer 210 may be formed through a similar process.

Then, electrolytic plating is performed on the metal film 203 using the metal film 203 as a plating power feeding layer with the resist layer 210 acting as a plating mask. In this example, electrolytic plating, that is, electrolytic Ni plating, is performed on the upper surface of the metal film 203 exposed from the opening patterns 210X and 210Y of the resist layer 210. This forms a metal layer 211 on the upper surface of the metal film 203 exposed from the opening pattern 210X and a metal layer 212 on the upper surface of the metal film 203 exposed from the opening pattern 210Y. The upper surface of the metal layer 211 is coplanar with the upper surface of the metal layer 212. The material of the metal layers 211 and 212 may be a material other than nickel as long as it is a conductive material that may be selectively etched and removed from the wiring layer 20 (refer to FIG. 2) in a subsequent step.

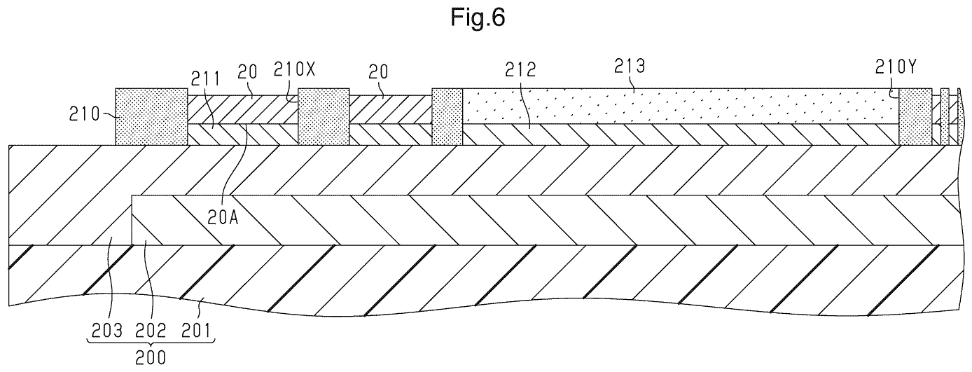

In the step illustrated in FIG. 6, a resist layer 213 is formed on the entire upper surface of the metal layer 212 formed in the opening pattern 210Y. The material of the resist layer 213 may be, for example, a material that resists plating in the plating process performed in the following step. The material of the resist layer 213 may be, for example, the same as the material of the resist layer 210. The resist layer 213 may be formed, for example, in the same manner as the resist layer 210.

Then, electrolytic plating, that is, electrolytic Cu plating, is performed on the metal layer 211 using the resist layers 210 and 213 as plating power feeding layers. This forms the wiring layer 20 on the metal layer 211 formed in the opening pattern 210X. In this state, the mounting surface 20A (i.e., lower surface) of the wiring layer 20 is formed contacting the upper surface of the metal layer 211. The wiring layer 20 is not formed on the metal layer 212, which is covered by the resist layer 213.

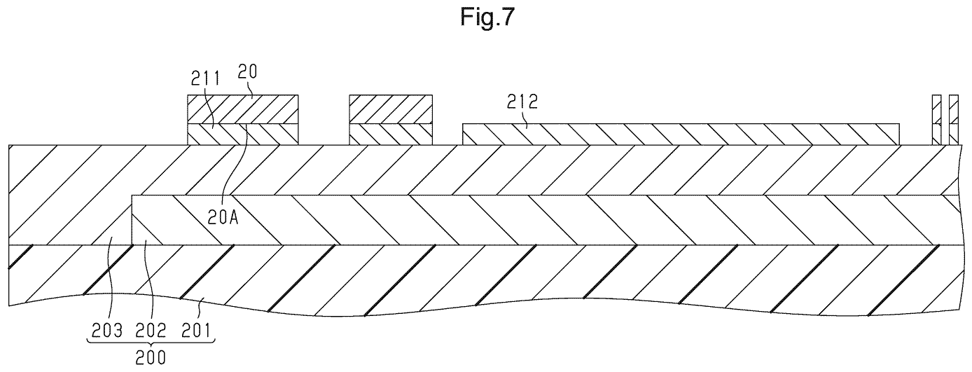

In the step illustrated in FIG. 7, the resist layers 210 and 213 of FIG. 6 are removed by an alkali delamination liquid (e.g., organic amine delamination liquid, caustic soda, acetone, or ethanol).

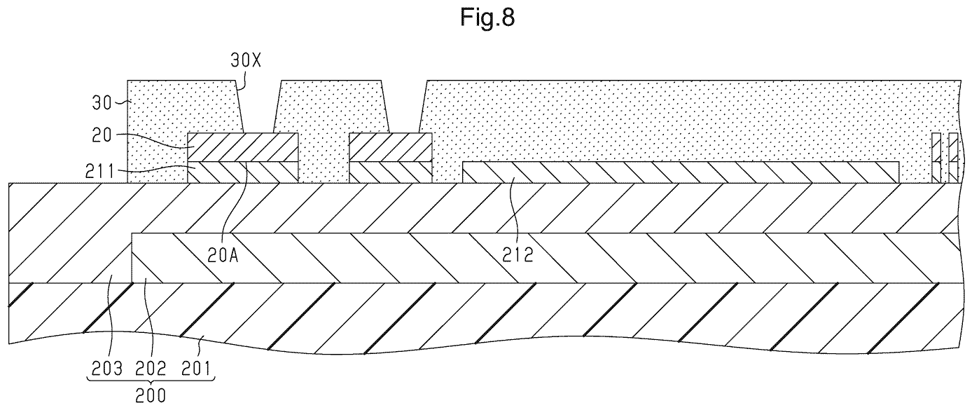

In the step illustrated in FIG. 8, the insulating layer 30, which covers the wiring layer 20, is formed on the upper surface of the metal film 203. The insulating layer 30 entirely covers the side surfaces of the metal layers 211 and 212 and entirely covers the side surfaces of the wiring layer 20. Further, the insulating layer 30 covers the entire upper surface of the metal layer 212. When using a resin film as the insulating layer 30, for example, the resin film is laminated onto the upper surface of the metal film 203. While pressing the resin film, the resin film is heated at a temperature of, for example, approximately 130° C. to 200° C., that is, greater than or equal to the curing temperature, and then cured to form the insulating layer 30. The resin film may be, for example, a film of a thermosetting resin of which the main component is an epoxy resin. When a liquid or paste of an insulative resin is used as the insulating layer 30, the liquid or paste of insulative resin is applied to the upper surface of the metal film 203 through a spin coating process or the like. The applied insulative resin is heated at temperature that is greater than or equal to the curing temperature and then cured to form the insulating layer 30. The liquid or paste of insulative resin may be, for example, a thermosetting resin of which the main component is an epoxy resin.

Then, through holes 30X are formed in the insulating layer 30 at given locations to expose parts of the upper surface of the wiring layer 20. The through holes 30X may be formed, for example, through laser processing using a CO₂ laser, a UV-YAG laser, or the like.

When forming the through holes 30X through laser processing, a desmearing process is performed to remove smeared resin from the surface of the wiring layer 20 exposed at the bottom of each through hole 30X. The desmearing process of this step may be, for example, a wet desmearing process using a potassium permanganate solution.

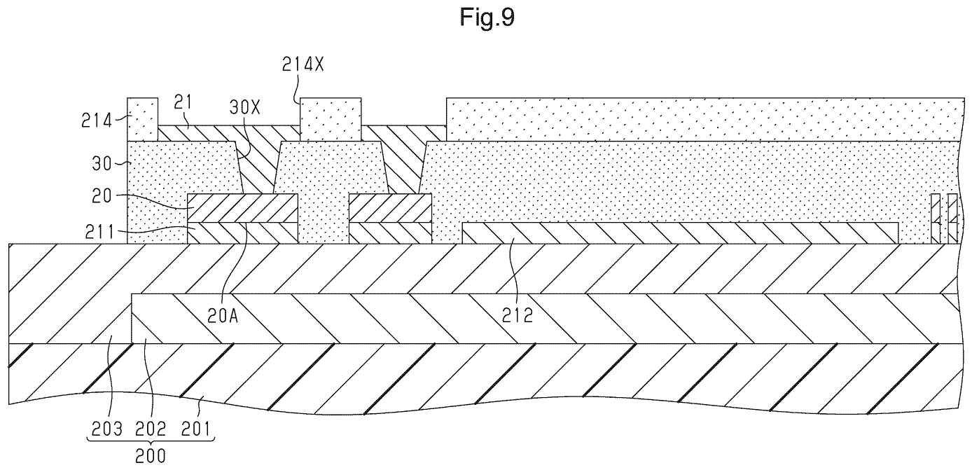

In the step illustrated in FIG. 9, a seed layer (not illustrated) is formed covering the entire upper surface of the insulating layer 30 and the entire wall surface of each through hole 30X. The seed layer is formed through, for example, a sputtering process or an electroless plating process. Then, a resist layer 214 including an opening pattern 214X at a given location is formed on the seed layer in a manner similar to the step illustrated in FIG. 5. The opening pattern 211X exposes the upper surface of the seed layer at parts corresponding to regions where the wiring layer 21 is formed. Then, electrolytic plating is performed on the seed layer using the seed layer as a plating power feeding layer with the resist layer 214 acting as a plating mask. This fills the through holes 30X with via wiring and forms the wiring layer 21 in the opening pattern 214X.

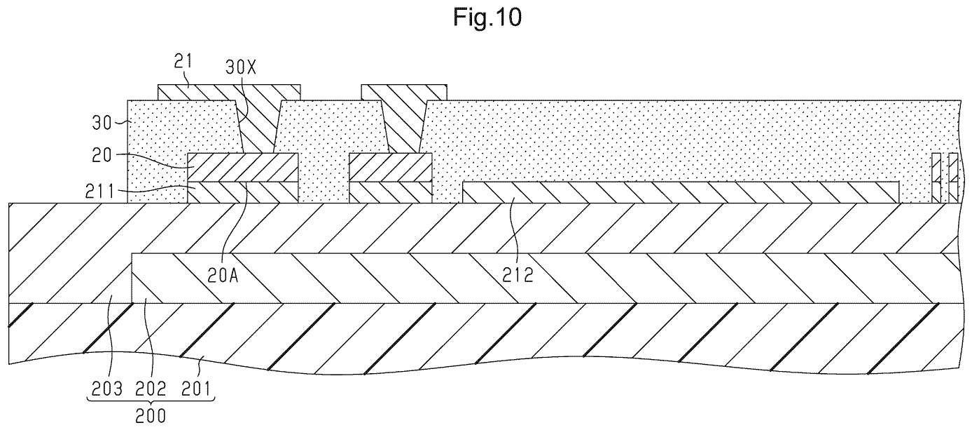

In the step illustrated in FIG. 10, the resist layer 214 of FIG. 9 is removed by an alkali delamination liquid (e.g., organic amine delamination liquid, caustic soda, acetone, or ethanol). Then, etching is performed to remove the unnecessary seed layer.

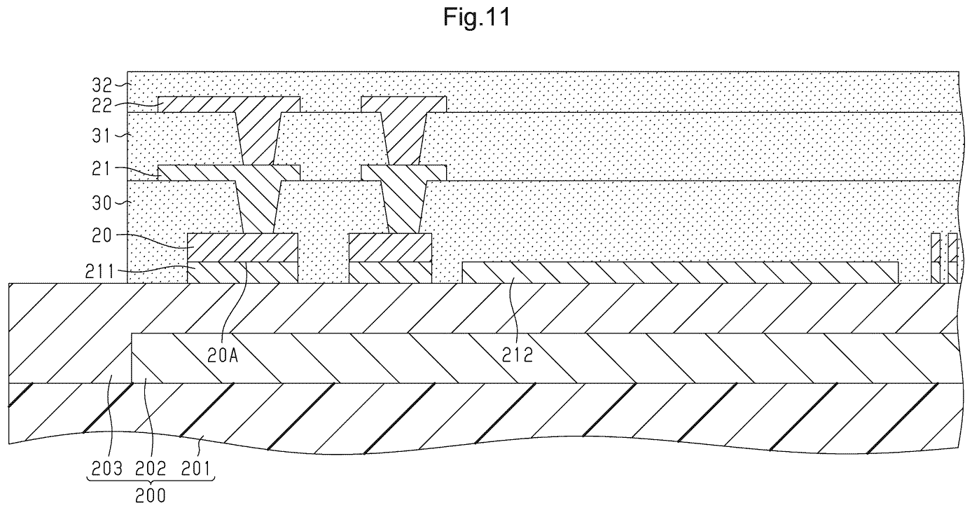

In the step illustrated in FIG. 11, the insulating layer 31 and the wiring layer 22 are formed on the upper surface of the insulating layer 30 in a manner similar to the steps of FIGS. 8 to 10. Further, the insulating layer 32 is formed on the upper surface of the insulating layer 31 covering the wiring layer 22. The insulating layer 32 is formed entirely on the upper and side surfaces of the wiring layer 22.

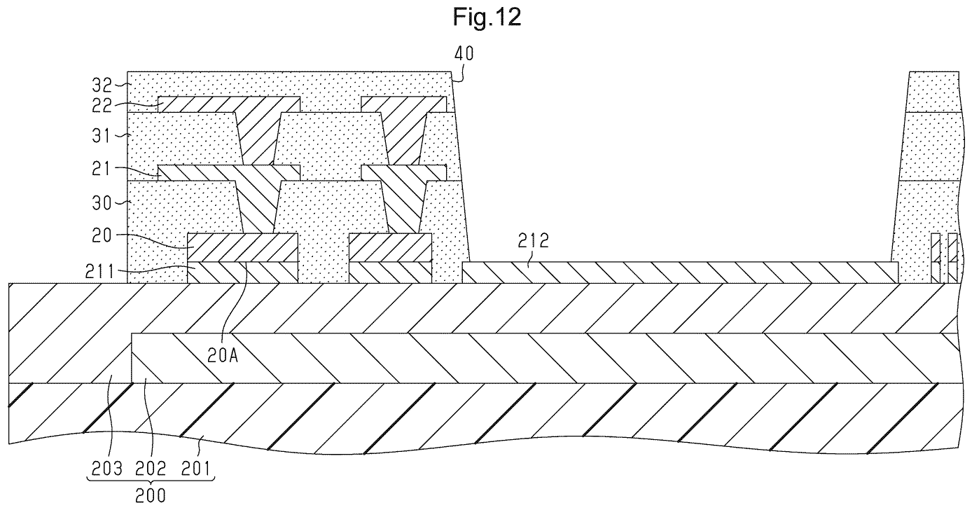

In the step illustrated in FIG. 12, the cavities 40 are formed, recessed from the upper surface of the insulating layer 32 toward the metal layer 212, to expose parts of the upper surface of the metal layer 212. The cavities 40 extend through the insulating layers 30, 31, and 32 in the thickness direction. The cavities 40 may be formed, for example, through laser processing using a CO₂ laser or a UV-YAG laser.

When forming the cavities 40 through laser processing, a desmearing process is performed to remove smeared resin from the surface of the metal film 212 exposed at the bottom portions of the cavities 40.

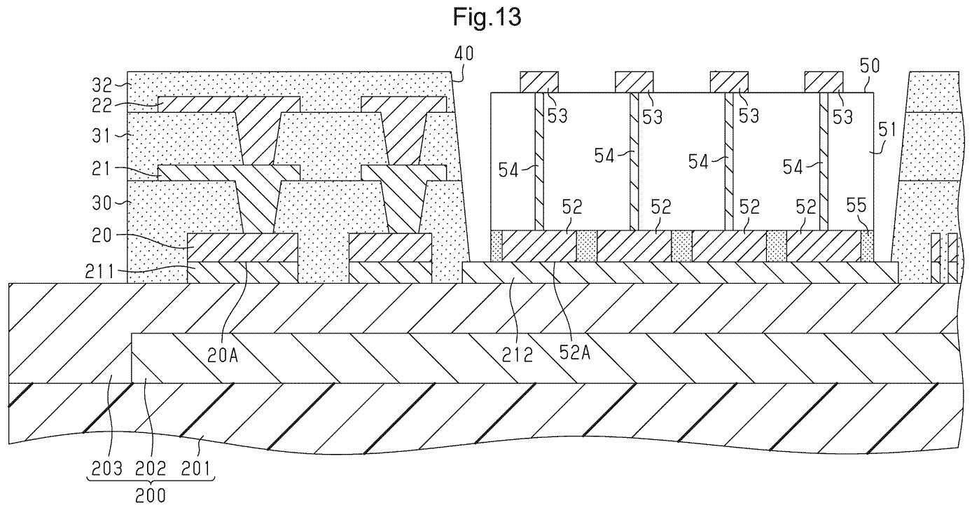

In the step illustrated in FIG. 13, the electronic components 50 are prepared, each including the main body 51, the first electrodes 52, the second electrodes 53, and the through-electrodes 54. Then, a mounter is used to fix the electronic components 50 to the upper surface of the metal film 212 exposed from the cavities 40 with the insulating resin 55, which is adhesive. The insulating resin 55 entirely covers the side surfaces of the first electrodes 52. The lower surface of the insulating resin 55 is bonded to the upper surface of the metal layer 212. The mounting surface 52A (i.e., lower surface) of each first electrode 52 is in contact with the upper surface of the metal layer 212. Thus, the mounting surface 52A of each first electrode 52 is coplanar with the mounting surface 20A of the wiring layer 20. The insulating resin 55 may be, for example, an adhesive agent in which a filler is mixed in a base resin, such as an epoxy resin.

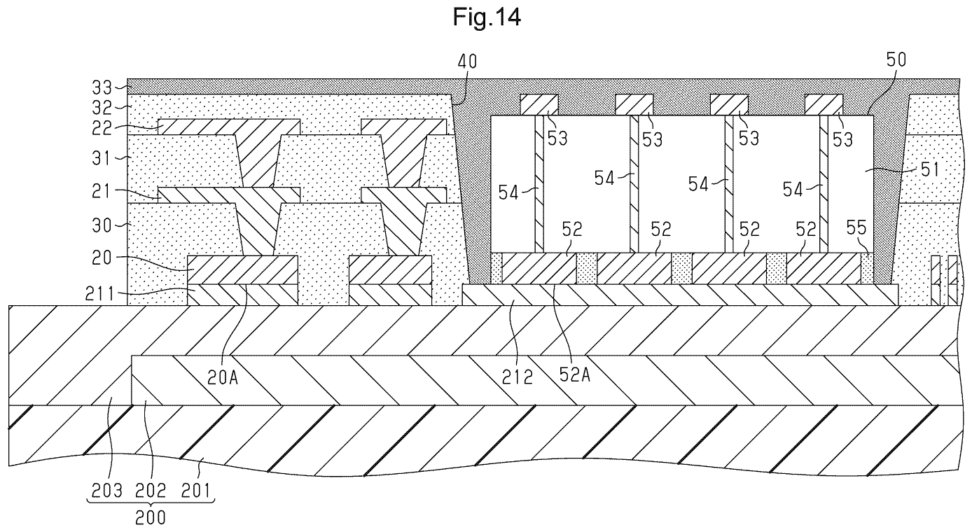

In the step illustrated in FIG. 14, the cavities 40 are filled with the insulating layer 33 that covers the upper surface of the insulating layer 32 in a manner similar to the step of FIG. 8. The insulating layer 33 entirely covers the side surfaces of the insulating resin 55 and entirely covers the surfaces of each electronic component 50 exposed from the insulating resin 55. The insulating layer 33 covers the entire upper surface of the metal film 212 exposed from the insulating resin 55.

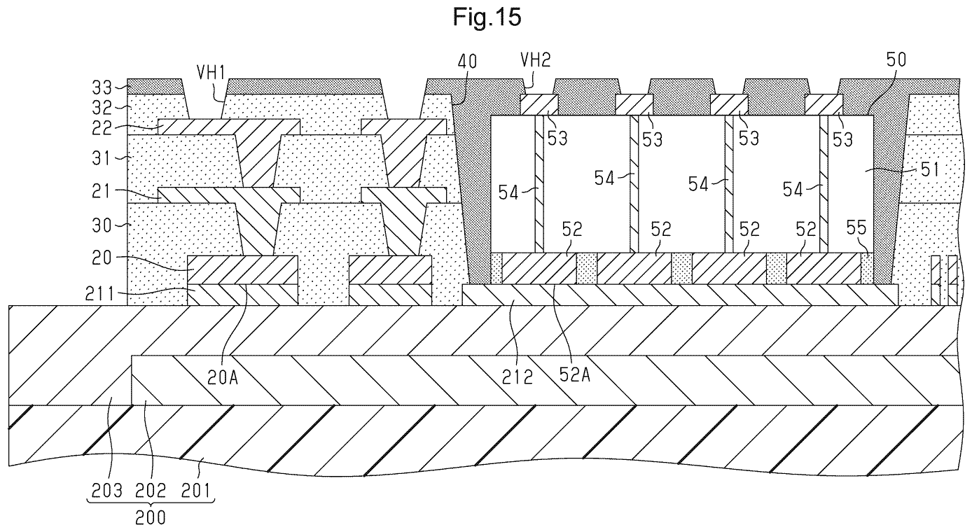

In the step illustrated in FIG. 15, the through holes VH1, which extend through the insulating layers 32 and 33 in the thickness direction and expose parts of the upper surface of the wiring layer 22, are formed at given locations in the insulating layers 32 and 33. The through holes VH1 may be formed, for example, through laser processing using a CO₂ laser. Further, the through holes VH2, each extending through the insulating layer 33 in the thickness direction and exposing a part of the upper surface of each second electrode 53, are formed at given locations in the insulating layer 33. The through holes VH2 may be formed, for example, through laser processing using a CO₂ laser. The through holes VH2 and the through holes VH1 may be formed, for example, in the same step or in different steps.

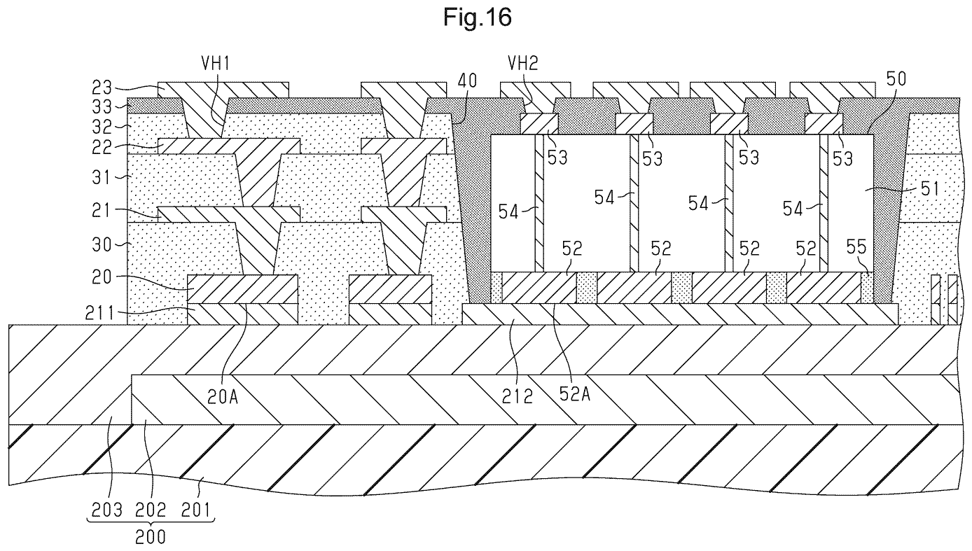

In the step illustrated in FIG. 16, the through holes VH1 are filled with via wiring, and the wiring layer 23, which is electrically connected by the via wiring to the wiring layer 22, is formed on the upper surface of the insulating layer 33 in a manner similar to the steps of FIGS. 9 and 10. Further, the through holes VH2 are filled with via wiring, and the wiring layer 23, which is electrically connected by the via wiring to the second electrodes 53, is formed on the upper surface of the insulating layer 33.

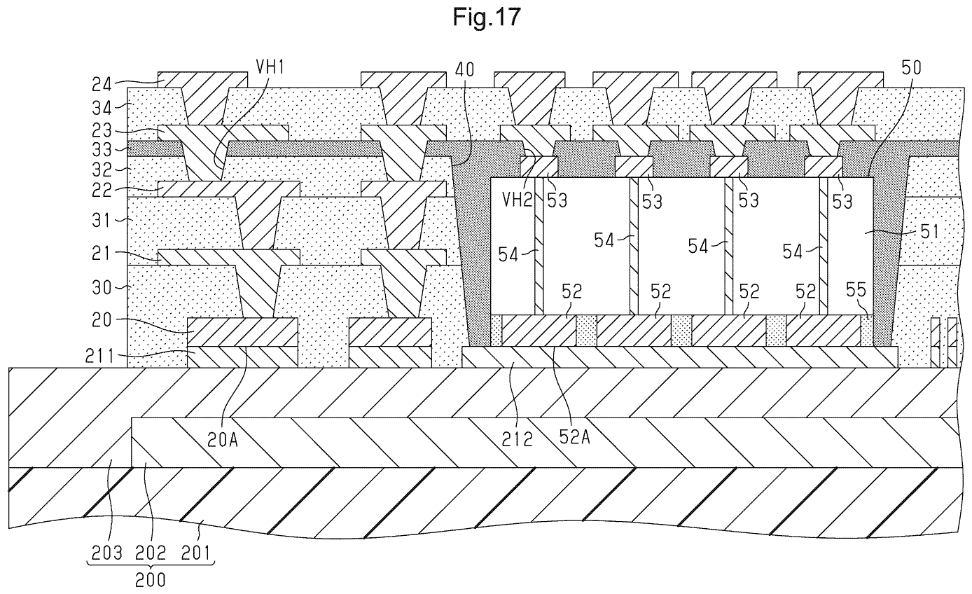

In the step illustrated in FIG. 17, the insulating layer 34 and the wiring layer 24 are sequentially formed on the upper surface of the insulating layer 33 in a manner similar to the steps of FIGS. 8 to 10.

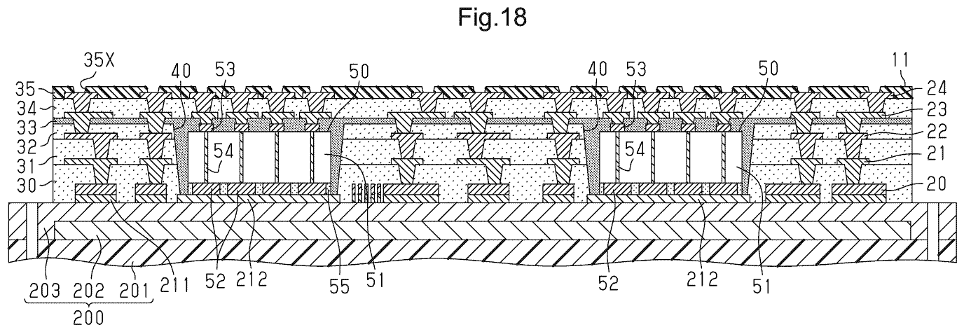

In the step illustrated in FIG. 18, the solder resist layer 35, which includes the openings 35X exposing parts of the upper surface of the wiring layer 24 as external connection pads, is formed on the upper surface of the insulating layer 34. The solder resist layer 35 may be formed by, for example, laminating a photosensitive solder resist film on or applying a liquid of solder resist to the insulating layer 34 and patterning the resist into a predetermined shape.

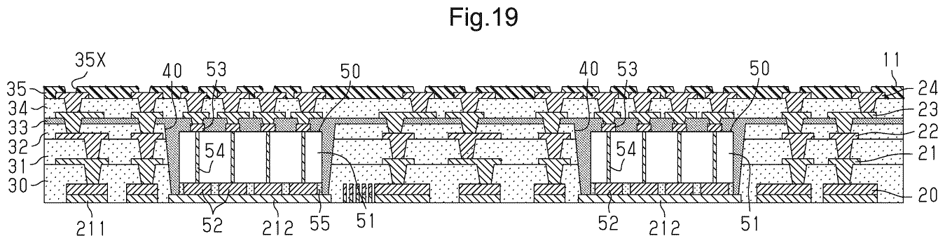

Then, a slicer or the like is used to cut away the peripheral region of the support 200. The peripheral region of the support 200 is the part extending outward from the peripheral surfaces of the insulating layers 30, 31, 32, 33, and 34 and the peripheral surfaces of the solder resist layer 35. Then, the support 200 is removed. The base 201 is first removed from the support 200. For example, the base 201 is mechanically removed from the metal films 202 and 203. Then, the metal films 202 and 203 are removed. For example, the metal films 202 and 203, which are Cu films, are selectively etched and removed from the metal layers 211 and 212. This exposes the lower surface of the insulating layer 30 and the lower surfaces of the metal layers 211 and 212 to the outside, as illustrated in FIG. 19.

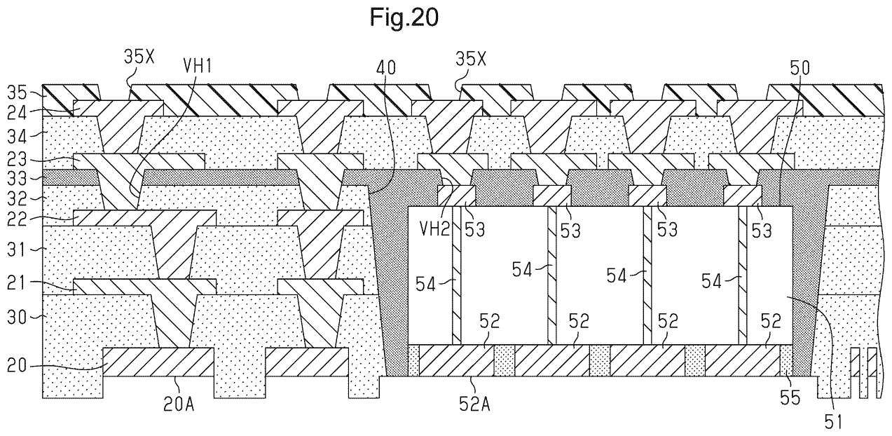

Then, the metal layers 211 and 212 are removed. The metal layers 211 and 212 are, for example, selectively etched and removed from the wiring layer 20 and the first electrodes 52. This exposes the mounting surface 20A (i.e., lower surface) of the wiring layer 20, the mounting surface 52A (i.e., lower surface) of each first electrode 52, the lower surface of the insulating resin 55, and the lower surface of the insulating layer 33 in the cavities 40 to the outside, as illustrated in FIG. 20. In this state, the mounting surface 20A of the wiring layer 20 is coplanar with the mounting surface 52A of each first electrode 52.

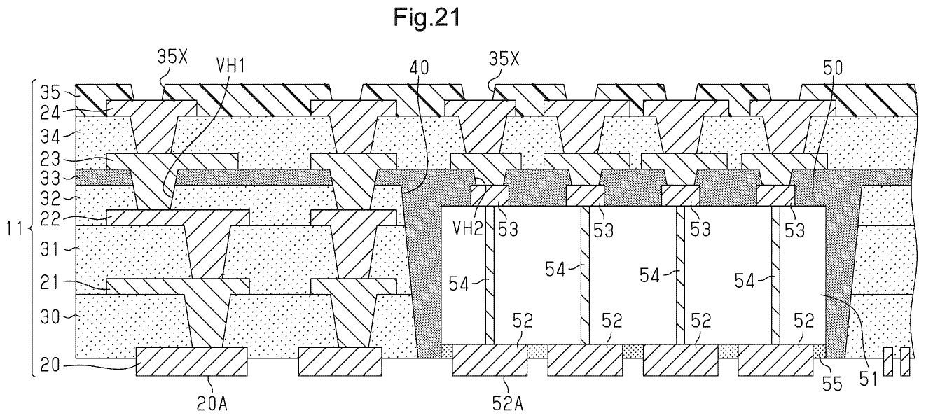

In the step illustrated in FIG. 21, the insulating layers 30 and 33 and the insulating resin 55 are thinned from the lower side. That is, the insulating layers 30 and 33 and the insulating resin 55, which are exposed by the removal of the metal layers 211 and 212 (refer to FIG. 19), are thinned from the lower side. In this example, the insulating layers 30 and 33 and the insulating resin 55 are thinned from the lower side so that the lower portions of the wiring layer 20 and the first electrodes 52 project downward beyond the lower surfaces of the insulating layers 30 and 33 and the insulating resin 55. The thinned lower surface of the insulating layer 30 is, for example, flush with the lower surface of the thinned insulating layer 33 and the lower surface of the thinned insulating resin 55. The insulating layers 30 and 33 and the insulating resin 55 may be thinned by performing, for example, an ashing process (dry etching using oxygen plasma).

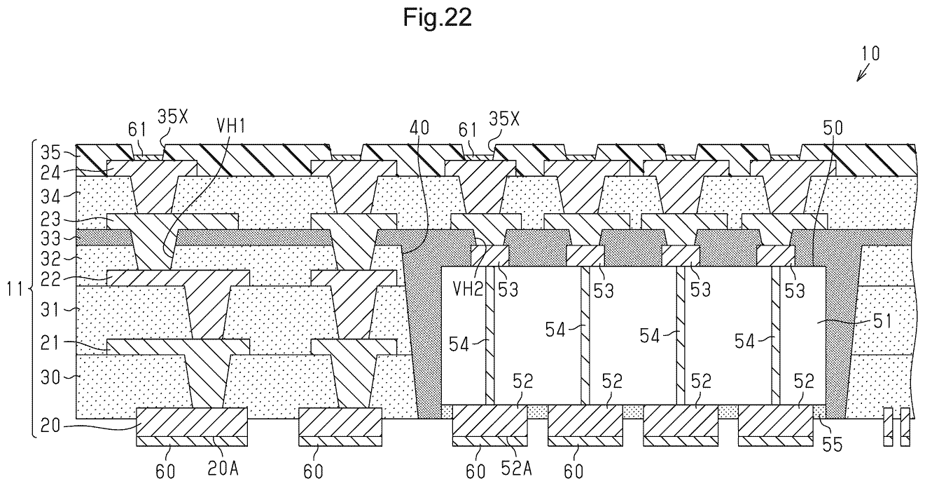

In the step illustrated in FIG. 22, the surface-processed layer 60 is formed on the mounting surface 20A of the wiring layer 20 and the mounting surface 52A of each first electrode 52. Further, the surface-processed layer 61 is formed on the upper surface of the wiring layer 24 exposed from the openings 35X of the solder resist layer 35. The surface-processed layers 60 and 61 are formed through, for example, an electroless plating process. The wiring substrate 10 in accordance with the first embodiment is manufactured through the steps described above.

### Method for Manufacturing the Semiconductor Device 1

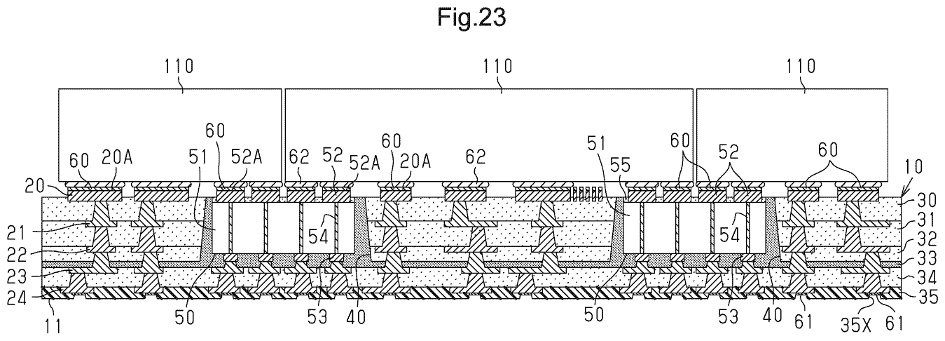

A method for manufacturing the semiconductor device 1 will now be described with reference to FIGS. 23 to 25. In FIGS. 23 to 25, the wiring substrate 10 is rotated by 180° from the state illustrated in FIG. 22.

In the step illustrated in FIG. 23, the semiconductor chips 110 (three in the first embodiment) are mounted on the wiring substrate 10. In this example, the three semiconductor chips 110 are flip-chip mounted on the wiring layer 20 and the first electrodes 52 of the wiring substrate 10. Each semiconductor chip 110 is electrically connected to the wiring layer 20 and the first electrodes 52 by the bonding members 62 and the surface-processed layer 60. Each semiconductor chip 110 mounted on the wiring substrate 10 overlies the wiring layer 20 and the first electrodes 52. In this state, the mounting surface 20A (upper surface in FIG. 23) of the wiring layer 20 is coplanar with the mounting surface 52A (upper surface in FIG. 23) of each first electrode 52. That is, the mounting surface 20A of the wiring layer 20 has the same height as the mounting surface 52A of each first electrode 52. This allows the semiconductor chips 110 to be readily mounted on the wiring layer 20 and the first electrodes 52 of the wiring substrate 10.

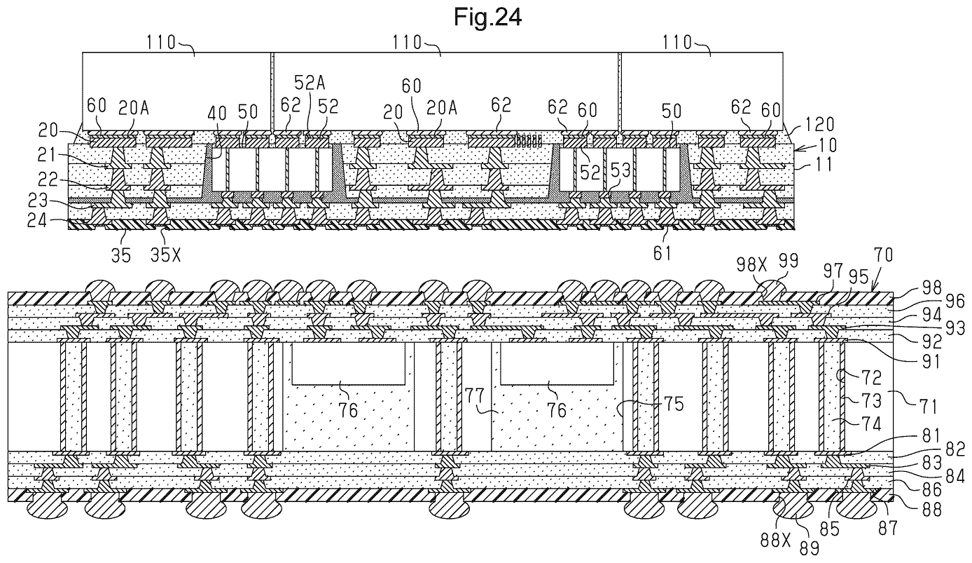

In the step illustrated in FIG. 24, the gaps between the semiconductor chips 110 and the wiring substrate 10 are filled with the underfill resin 120. Then, the underfill resin 120 is cured.

In the step illustrated in FIG. 24, the substrate 70 incorporating the electronic components 76 is formed. The substrate 70 may be formed through a known process. Thus, the process will not be described in detail. The bonding members 99 are formed on the wiring layer 97, which are exposed from the openings 98X in the solder resist layer 98 of the substrate 70.

Then, the wiring substrate 10, on which the semiconductor chips 110 are mounted, is arranged above the substrate 70. The wiring substrate 10 is arranged so that the solder resist layer 35 faces the solder resist layer 98 of the substrate 70. Further, the wiring substrate 10 is arranged so that the surface-processed layer 61 faces the bonding members 99.

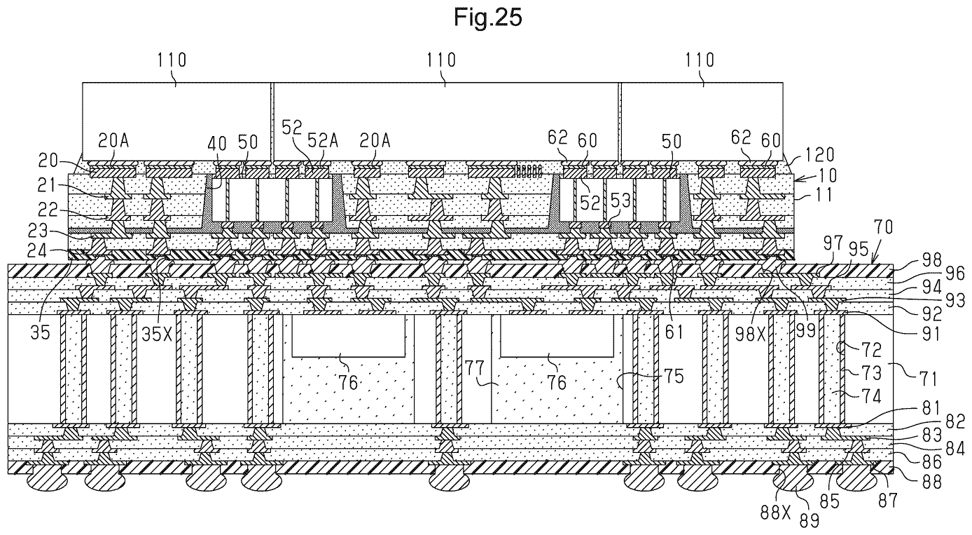

In the step illustrated in FIG. 25, the wiring substrate 10 is mounted on the substrate 70. In this example, the surface-processed layer 61 of the wiring substrate 10 is bonded onto the bonding members 99 of the substrate 70. This electrically connects the wiring layer 24 of the wiring substrate 10 to the wiring layer 97 of the substrate 70 through the surface-processed layer 61 and the bonding members 99.

The gaps between the substrate 70 and the wiring substrate 10, which are bonded together, are filled with the underfill resin 100 (FIG. 3). Then, the underfill resin 100 is cured.

The semiconductor device 1 illustrated in FIG. 3 is manufactured through the steps described above.

In the first embodiment, the wiring layer 20 is an example of a first wiring layer, the wiring layer 23 is an example of a second wiring layer, the insulating layer 30 is an example of a first insulating layer, the insulating layers 30, 31, and 32 are an example of an N number of insulating layers, and the insulating layer 33 is an example of a capping insulating layer. Further, each electronic component 50 is one example of a first electronic component, each semiconductor chip 110 is one example of a second electronic component, the mounting surface 20A is one example of a first mounting surface, the mounting surface 52A is one example of a second mounting surface, and the support 200 and the metal layers 211 and 212 are one example of a support.

### Advantages of the First Embodiment

The first embodiment has the advantages described below.
(1-1) The wiring layer 20 includes the mounting surface 20A exposed from the insulating layer 30. The first electrodes 52 of the electronic components 50 each include the mounting surface 52A exposed from the insulating layer 33 in the cavities 40. The mounting surface 52A is coplanar with the mounting surface 20A. In this structure, when the semiconductor chips 110 are mounted on the mounting surface 20A and the mounting surfaces 52A, the semiconductor chips 110 are mounted on the mounting surfaces 20A and 52A that have the same height. This allows the semiconductor chips 110 to be mounted on the wiring layer 20 and the first electrodes 52 of the wiring substrate 10 more readily than when the mounting surface 20A extends along a plane differing from that of the mounting surfaces 52A.
(1-2) The wiring substrate 10 is a coreless substrate. This allows the entire wiring substrate 10 to be thinner than when the wiring substrate 10 is a cored substrate.
(1-3) The wiring layer 20 projects downward beyond the lower surface (third surface) of the insulating layer 30, which faces the downward direction (first direction). Further, the first electrodes 52 project downward beyond the lower surface (second surface) of the insulating resin 55, which faces the downward direction. In this structure, the wiring layer 20 and the first electrodes 52 extend downward, post-like, beyond the insulating layer 30 and the lower surface of the insulating resin 55. This meets demands for miniaturization of the wiring layer 20 and the first electrodes 52, which arise when, for example, the semiconductor chips 110 are highly integrated and highly sophisticated.

### Second Embodiment

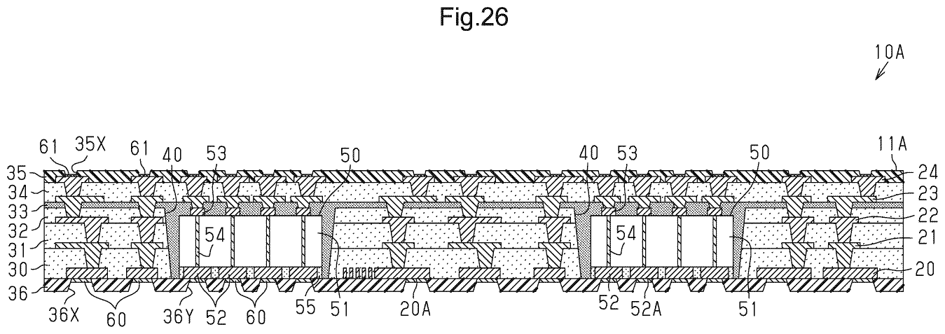

A second embodiment will now be described with reference to FIGS. 26 to 39. The description hereafter will focus on differences from the first embodiment. The same reference numerals are given to those components that are the same as the corresponding components illustrated in FIGS. 1 to 25. Such components will not be described in detail.

### Structure of the Wiring Substrate 10A

As illustrated in FIG. 26, a wiring substrate 10A includes a wiring structure 11A, one or more (two in the second embodiment) cavities 40 formed in the wiring structure 11A, and one or more (two in the second embodiment) electronic components 50 disposed in the cavities 40. The wiring substrate 10A incorporates the electronic components 50.

### The Wiring Structure 11A

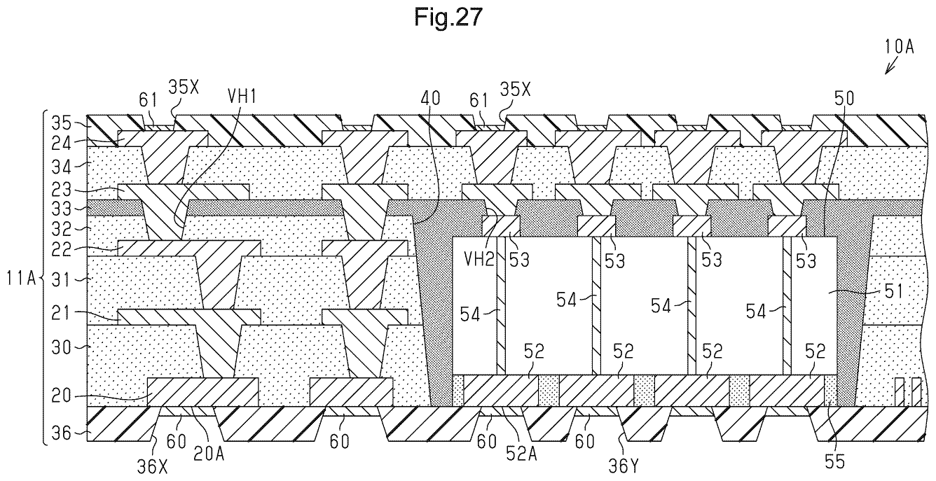

As illustrated in FIG. 27, in the wiring structure 11A of the second embodiment, the lower surface of the insulating layer 30 is flush with the mounting surface 20A of the wiring layer 20, the lower surfaces of the parts of the insulating layer 33 in the cavities 40, the lower surface of the insulating resin 55, and the mounting surface 52A of each first electrode 52. Thus, in the wiring structure 11A, the mounting surface 20A (i.e., lower surface) of the wiring layer 20 is coplanar with the mounting surface 52A (i.e., lower surface) of each first electrode 52.

The insulating layer 30 of the second embodiment covers the upper surface of the wiring layer 20 and entirely covers the side surfaces of the wiring layer 20. In other words, the wiring layer 20 of the second embodiment is entirely embedded in the insulating layer 30. The entire mounting surface 20A of the wiring layer 20 is exposed from the insulating layer 30.

The insulating resin 55 of the second embodiment entirely covers the side surfaces of the first electrodes 52. In other words, the first electrodes 52 of the second embodiment are entirely embedded in the insulating resin 55. The entire mounting surface 52A of each first electrode 52 is exposed from the insulating resin 55.

The wiring structure 11A includes a solder resist layer 36 formed on the lower surface of the insulating layer 30. The solder resist layer 36, formed on the lower surface of the insulating layer 30, covers parts of the mounting surface 20A of the wiring layer 20 and a part of the mounting surface 52A of each first electrode 52. The solder resist layer 36 is the outermost insulating layer arranged on the outermost layer (here, the lowermost layer) of the wiring substrate 10A. The thickness from the mounting surface 20A of the wiring layer 20 to the lower surface of the solder resist layer 36 may be, for example, approximately 12 μm to 50 μm. The solder resist layer 36 may be formed from, for example, a material of which the main component is a photosensitive resin. The solder resist layer 36 may be formed from, for example, a photosensitive insulative resin of which the main component is a phenol resin or a polyimide resin.

The solder resist layer 36 includes openings 36X, which expose parts of the mounting surface 20A of the wiring layer 20, and openings 36Y, which expose part of the mounting surface 52A of each first electrode 52. The openings 36X and 36Y are, for example, tapered and reduced in diameter (opening width) from the lower side (lower surface of solder resist layer 36) toward the upper side as viewed in FIG. 27. The openings 36X and 36Y each have, for example, the form of a truncated cone so that the diameter at the lower end is greater than the diameter at the upper end.

The surface-processed layer 60 is formed on the mounting surface 20A exposed from each opening 36X and the mounting surface 52A exposed from each opening 36Y, when required.

### Method for Manufacturing the Wiring Substrate 10A

A method for manufacturing the wiring substrate 10A will now be described. To simplify illustration, elements that will consequently become the final elements of the wiring substrate 10A are given the same reference characters as the final elements.

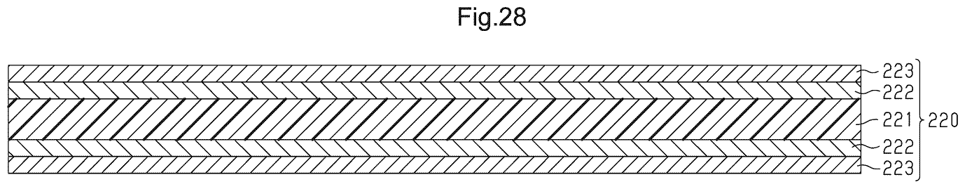

In the step illustrated in FIG. 28, a support 220 is prepared. The support 220 is constructed by, for example, sequentially stacking a metal foil 222 and a metal film 223 on both upper and lower surfaces of a base 221. The base 221 is formed from, for example, a prepreg obtained by impregnating a reinforcement material such as a woven or non-woven cloth of glass fibers, aramid fibers, or liquid crystal polymer (LCP) fibers with a thermosetting insulative resin, such as an epoxy resin or a polyimide resin. The metal foils 222 entirely cover, for example, the upper and lower surfaces of the base 221. Each metal foil 222 is, for example, a copper foil. Each metal film 223 entirely covers, for example, the upper surface or the lower surface of the corresponding metal foil 222. The metal film 223 is, for example, a nickel (Ni) plating film. The material of the metal foils 222 is not limited to copper and may be a metal other than copper. Further, the material of the metal films 223 may be a material other than nickel as long as it is a conductive material that may be selectively etched and removed from the wiring layer 20 (refer to FIG. 27) in a subsequent step.

In a manufacturing method in accordance with the second embodiment, a structure corresponding to part of the wiring substrate 10A is formed on both upper and lower surfaces of the support 220. For the sake of brevity, the description illustrates only the structure formed on the upper surface of the support 220.

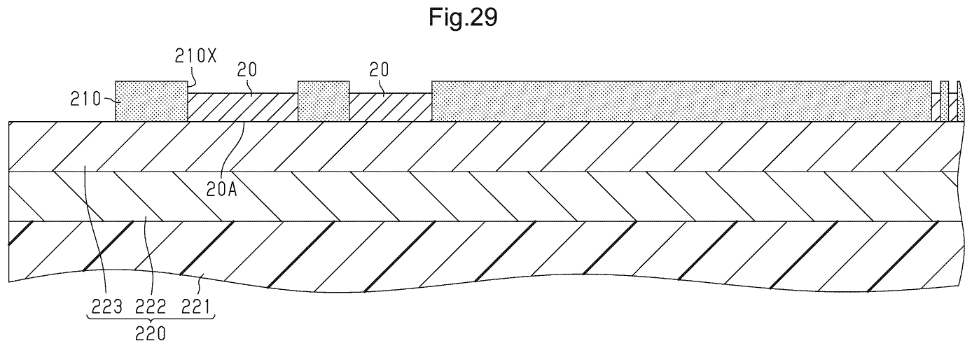

In the step illustrated in FIG. 29, the resist layer 210, which includes the opening pattern 210X, is formed on the upper surface of the metal film 223 of the support 220 in a manner similar to the step illustrated in FIG. 5.

Then, electrolytic plating, that is, electrolytic Cu plating, is performed on the upper surface of the metal film 223 exposed from the opening pattern 210X of the resist layer 210. This forms the wiring layer 20 on the upper surface of the metal film 223 exposed from the opening pattern 210X. In this state, the mounting surface 20A (i.e., lower surface) of the wiring layer 20 is formed contacting the upper surface of the metal film 223.

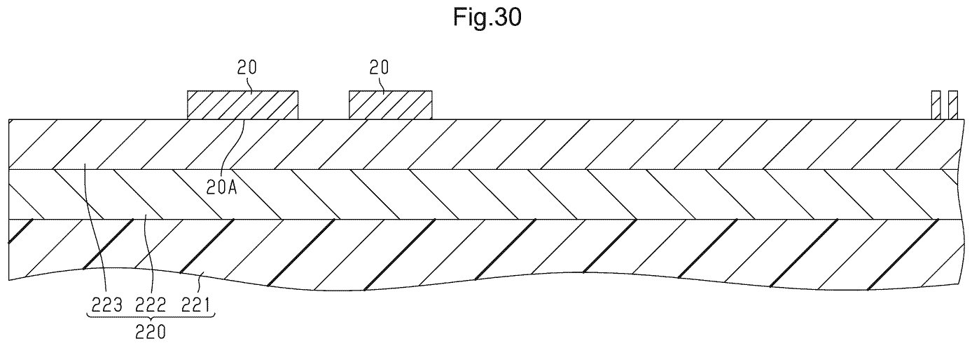

In the step illustrated in FIG. 30, the resist layer 210 illustrated in FIG. 29 is removed by an alkali delamination liquid in a manner similar to the step illustrated in FIG. 7.

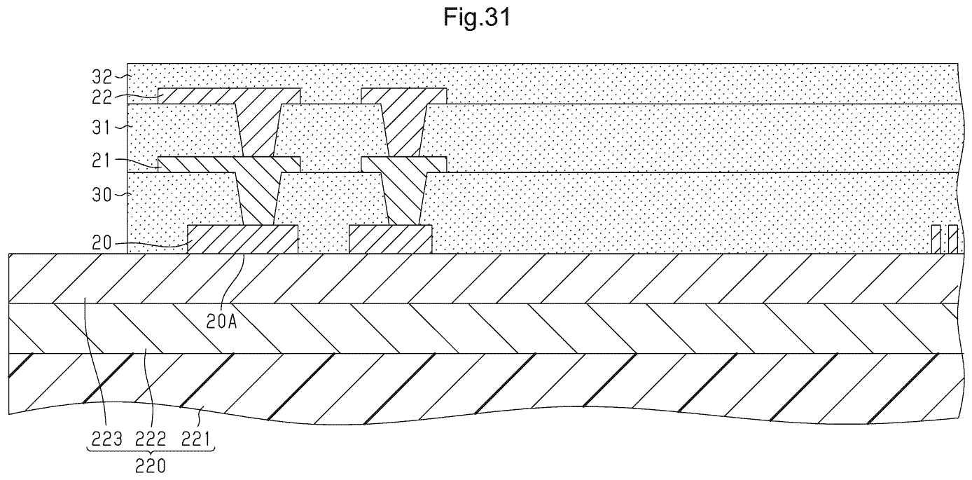

In the step illustrated in FIG. 31, the insulating layer 30, the wiring layer 21, the insulating layer 31, the wiring layer 22, and the insulating layer 32 are sequentially stacked on the upper surface of the metal film 223 in a manner similar to the steps illustrated in FIGS. 8 to 10.

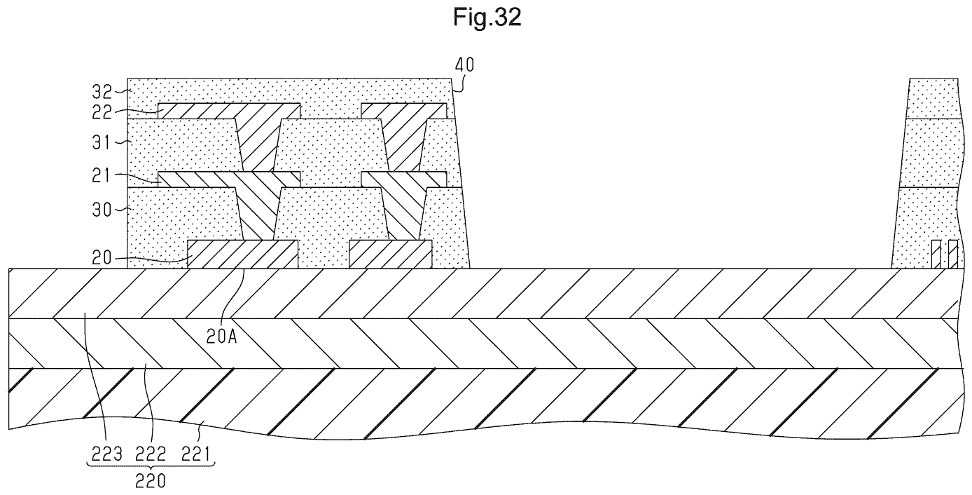

In the step illustrated in FIG. 32, the cavities 40, which are recessed from the upper surface of the insulating layer 32 toward the support 220, are formed to expose parts of the upper surface of the metal film 223 in a manner similar to the step illustrated in FIG. 12. The cavities 40 extend through the insulating layers 30, 31, and 32 in the thickness direction.

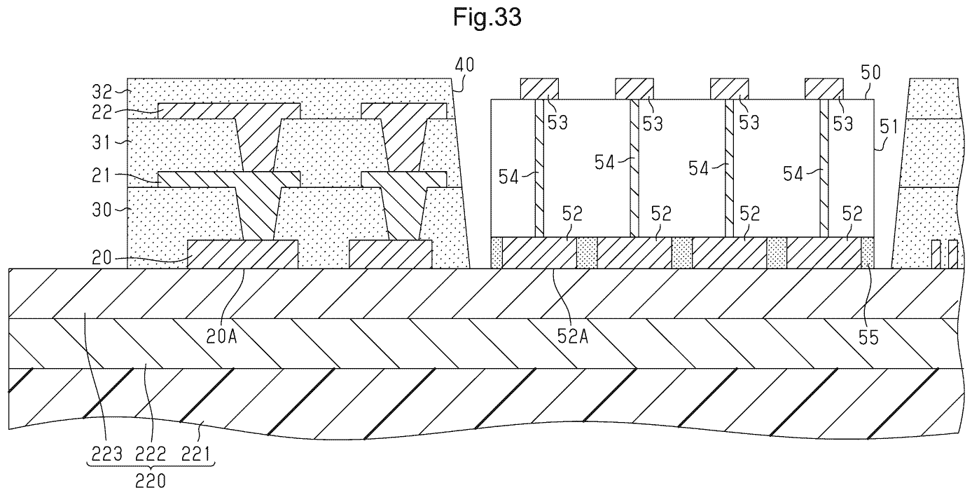

In the step illustrated in FIG. 33, a mounter is used to fix the electronic components 50 to the upper surface of the metal film 223 exposed from the cavities 40 with the insulating resin 55, which is adhesive, in a manner similar to the step of FIG. 13. In this state, the mounting surface 52A of each first electrode 52 is in contact with the metal film 223. Thus, the mounting surface 52A of each first electrode 52 is coplanar with the mounting surface 20A of the wiring layer 20.

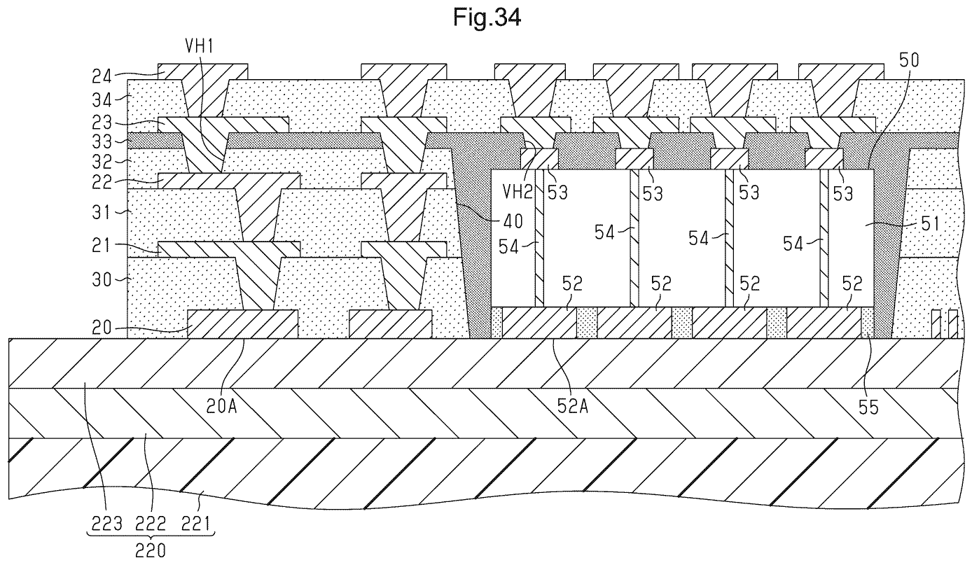

In the step illustrated in FIG. 34, the cavities 40 are filled with the insulating layer 33 that covers the upper surface of the insulating layer 32 in a manner similar to the step of FIG. 8.

Then, steps similar to the steps illustrated in FIGS. 8 to 10 are performed to sequentially form the wiring layer 23, the insulating layer 34, and the wiring layer 24 on the upper surface of the insulating layer 33.

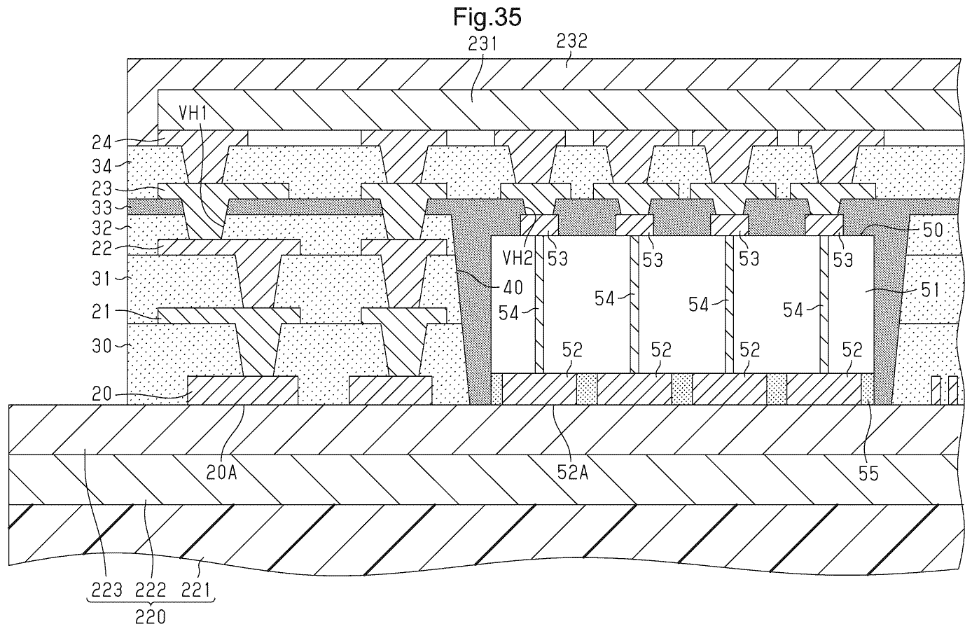

In the step illustrated in FIG. 35, a first protecting portion 231, which covers the upper surface of the wiring layer 24, is formed on the upper surface of the wiring layer 24, and a second protecting portion 232, which covers the upper surface of the first protecting portion 231, is formed on the upper surface of the insulating layer 34. The second protecting portion 232 covers the upper surface of the insulating layer 34 at the outer side of the first protecting portion 231. The second protecting portion 232 entirely covers the side surfaces of the wiring layer 24 that are located at the outermost side in the planar direction and entirely covers the side surfaces of the first protecting portion 231.

Then, the base 221 is removed from the support 220. For example, the base 221 is mechanically removed from the metal foil 222.

The metal foil 222 is then removed. For example, the metal foil 222 is selectively etched and removed from the metal film 223. The wiring layer 24 is covered by the first protecting portion 231 and the second protecting portion 232 and thus not etched and removed in this step.

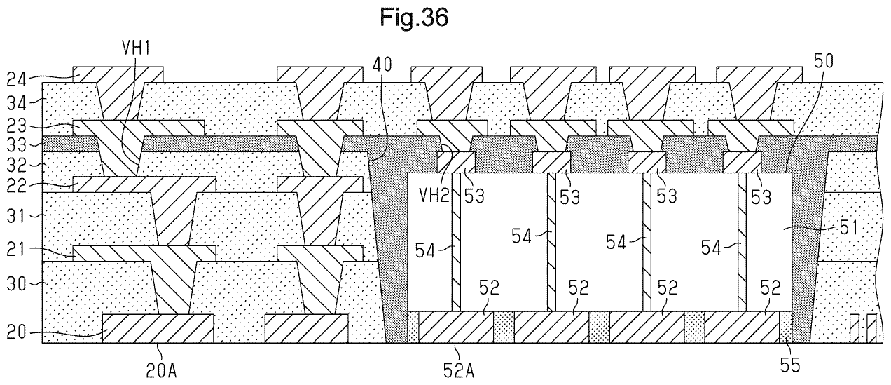

Then, the metal film 223 is removed. For example, the metal film 223 is etched and removed. The metal film 223 is, for example, selectively etched and removed from the wiring layer 20. This exposes the lower surfaces of the insulating layers 30 and 33, the mounting surface 20A of the wiring layer 20, the lower surface of the insulating resin 55, and the mounting surface 52A of each first electrode 52 to the outside, as illustrated in FIG. 36. In this state, the lower surfaces of the insulating layers 30 and 33, the mounting surface 20A of the wiring layer 20, the lower surface of the insulating resin 55, and the mounting surface 52A of each first electrode 52 that were in contact with the upper surface of the metal film 223 (refer to FIG. 35) are shaped in conformance with the upper surface (flat surface in this case) of the metal film 223. Therefore, the lower surfaces of the insulating layers 30 and 33 and the mounting surface 20A of the wiring layer 20 are flush with the lower surface of the insulating resin 55 and the mounting surface 52A of each first electrode 52.

Then, the first protecting portion 231 and the second protecting portion 232, which are illustrated in FIG. 35, are removed. For example, the first protecting portion 231 and the second protecting portion 232 are mechanically removed from the insulating layer 34.

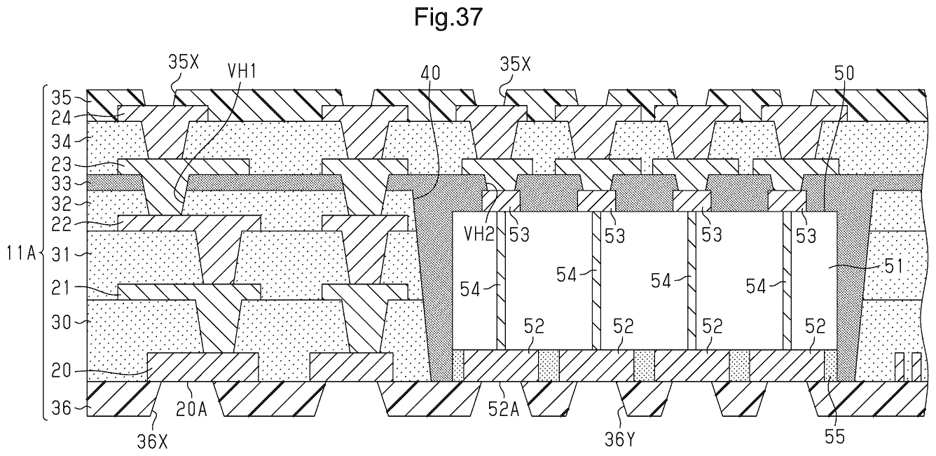

In the step illustrated in FIG. 37, the solder resist layer 36, which includes the openings 36X and 36Y, is formed on the lower surface of the insulating layer 30, and the solder resist layer 35, which includes the openings 35X, is formed on the upper surface of the insulating layer 34, in a manner similar to the step of FIG. 18.

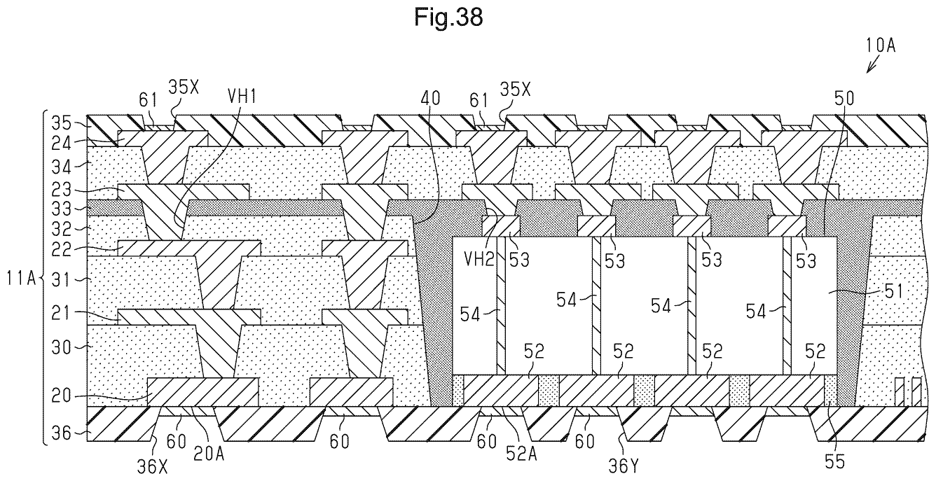

In the step illustrated in FIG. 38, the surface-processed layer 60 is formed on the mounting surfaces 20A and 52A that are exposed from the openings 36X and 36Y, and the surface-processed layer 61 is formed on the upper surface of the wiring layer 24 that is exposed from the openings 35X, in a manner similar to the step of FIG. 22. The wiring substrate 10A in accordance with the second embodiment is manufactured through the steps described above.

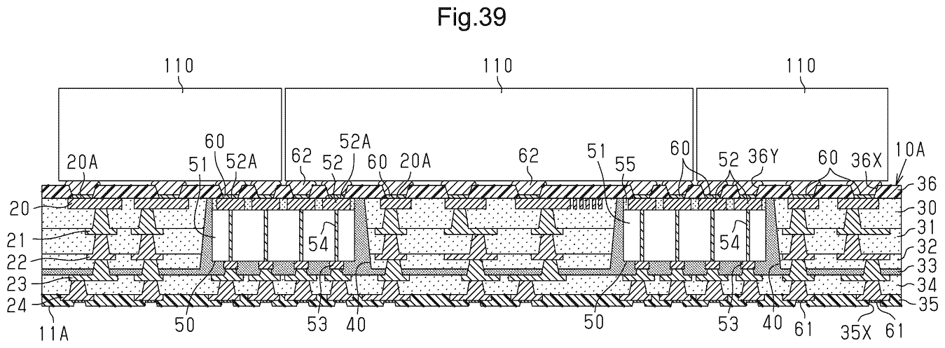

As illustrated in FIG. 39, the semiconductor chips 110 (three in the second embodiment) are mounted on the wiring substrate 10A. FIG. 39 illustrates the wiring substrate 10A in a state rotated 180° from the state of FIG. 38.

Each semiconductor chip 110 is flip-chip mounted on the wiring layer 20 and the first electrodes 52 of the wiring substrate 10A. Each semiconductor chip 110 is electrically connected to the wiring layer 20 and the first electrodes 52 by the bonding members 62 and the surface-processed layer 60. Each semiconductor chip 110 mounted on the wiring substrate 10A overlies the wiring layer 20 and the first electrodes 52. In this state, the mounting surface 20A (upper surface in FIG. 39) of the wiring layer 20 is coplanar with the mounting surface 52A (upper surface in FIG. 39) of each first electrode 52. This allows the semiconductor chips 110 to be readily mounted on the wiring layer 20 and the first electrodes 52 of the wiring substrate 10A.

The bonding members 62 are bonded to the surface-processed layer 60, which is formed on the mounting surfaces 20A and 52A exposed from the openings 36X and 36Y. For example, the openings 36X and 36Y are filled with the bonding members 62.

In the second embodiment, each opening 36X is one example of a first opening, and each opening 36Y is one example of a second opening.

### Advantages of the Second Embodiment

The second embodiment has advantages (1-1) and (1-2) of the first embodiment.

### Third Embodiment

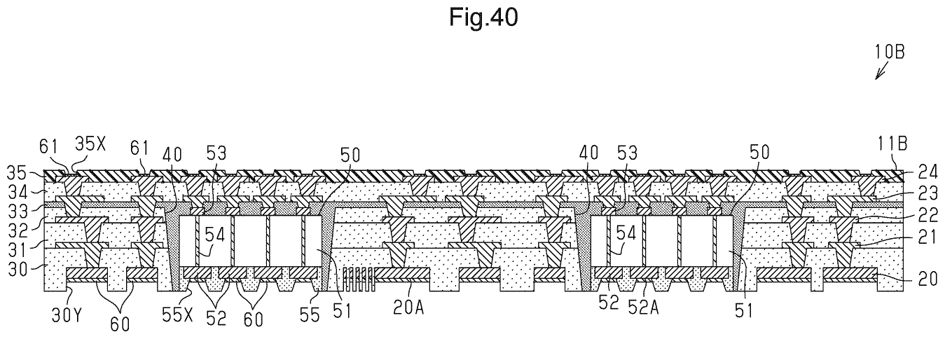

A third embodiment will now be described with reference to FIGS. 40 to 53. The description hereafter will focus on differences from the first embodiment. The same reference numerals are given to those components that are the same as the corresponding components illustrated in FIGS. 1 to 39. Such components will not be described in detail.

### Structure of the Wiring Substrate 10B

As illustrated in FIG. 40, a wiring substrate 10B includes a wiring structure 11B, one or more (two in the third embodiment) cavities 40 formed in the wiring structure 11B, and one or more (two in the third embodiment) electronic components 50 disposed in the cavities 40. The wiring substrate 10B incorporates the electronic components 50.

### The Wiring Structure 11B

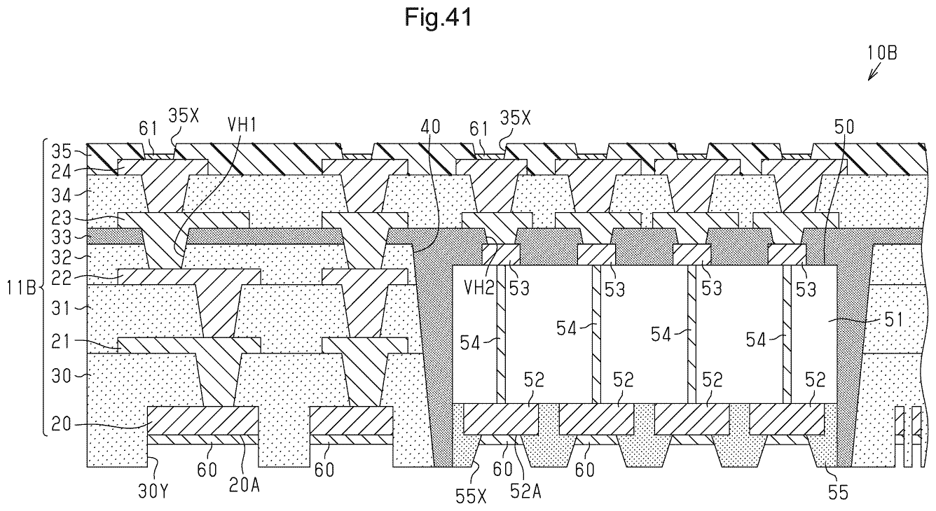

As illustrated in FIG. 41, in the wiring structure 11B of the third embodiment, the mounting surface 20A of the wiring layer 20 and the mounting surface 52A of each first electrode 52 are recessed upward beyond the lower surface of the insulating layer 30. In the wiring structure 11B, the mounting surfaces 20A and 52A are located toward the upper direction from the lower surface of the insulating resin 55. In other words, the lower surface of the insulating layer 30 and the lower surface of the insulating resin 55 are located toward the downward direction from the mounting surfaces 20A and 52A. In the wiring structure 11B, the mounting surface 20A is coplanar with each mounting surface 52A.

The insulating layer 30 of the third embodiment covers the upper surface of the wiring layer 20 and entirely covers the side surfaces of the wiring layer 20. The lower surface of the insulating layer 30 includes openings 30Y that are recessed upward from the lower surface of the insulating layer 30 and expose the mounting surface 20A of the wiring layer 20. The openings 30Y entirely expose the mounting surface 20A of the wiring layer 20. The openings 30Y each have, for example, a wall surface extending perpendicular to the lower surface of the insulating layer 30.

The insulating resin 55 of the third embodiment entirely covers the side surfaces of the first electrodes 52. The lower surface of the insulating resin 55 includes openings 55X that are recessed upward from the lower surface of the insulating resin 55 and expose a part of the mounting surface 52A of each first electrode 52. The openings 55X are, for example, tapered and reduced in diameter (opening width) from the lower side (lower surface of insulating resin 55) toward the upper side as viewed in FIG. 41. The openings 55X each have, for example, the form of a truncated cone so that the diameter at the lower end is greater than the diameter at the upper end.

The parts of the insulating layer 33 in the cavities 40 entirely cover the side surfaces of the insulating resin 55. The lower surface of each part of the insulating layer 33 in the cavities 40 is located toward the downward direction from the mounting surface 20A of the wiring layer 20 and the mounting surface 52A of each first electrode 52.

In the wiring structure 11B, the lower surface of the insulating layer 30 and the lower surface of each part of the insulating layer 33 in the cavities 40 are flush with the lower surface of the insulating resin 55.

### Method for Manufacturing the Wiring Substrate 10B

A method for manufacturing the wiring substrate 10B will now be described. To simplify illustration, elements that will consequently become the final elements of the wiring substrate 10B are given the same reference characters as the final elements.

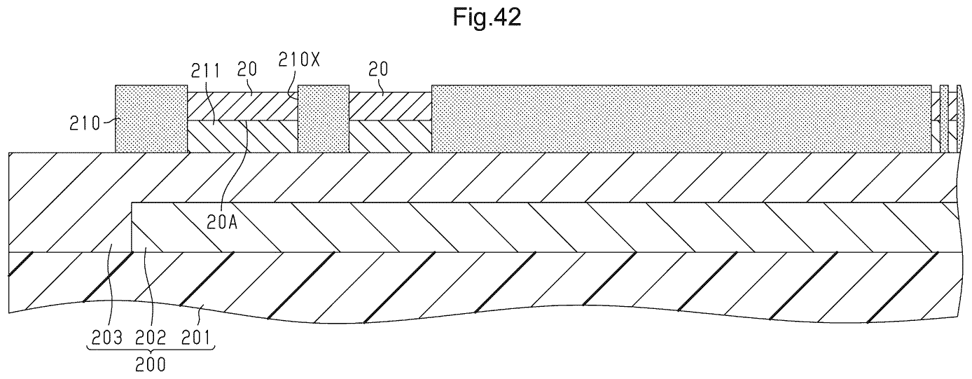

In the step illustrated in FIG. 42, the support 200 is prepared. Then, the resist layer 210, which includes the opening pattern 210X, is formed on the upper surface of the metal film 203 of the support 200 in a manner similar to the step illustrated in FIG. 5.

Then, electrolytic plating, that is, electrolytic Ni plating, is performed on the upper surface of the metal film 203 exposed from the opening pattern 210X of the resist layer 210. This forms the metal layer 211 on the upper surface of the metal film 203 exposed from the opening pattern 210X. Then, electrolytic plating, that is, electrolytic Cu plating, is performed on the metal layer 211 using the metal film 203 as a plating power feeding layer. This forms the wiring layer 20 on the metal layer 211. In this state, the mounting surface 20A (i.e., lower surface) of the wiring layer 20 is formed contacting the upper surface of the metal layer 211.

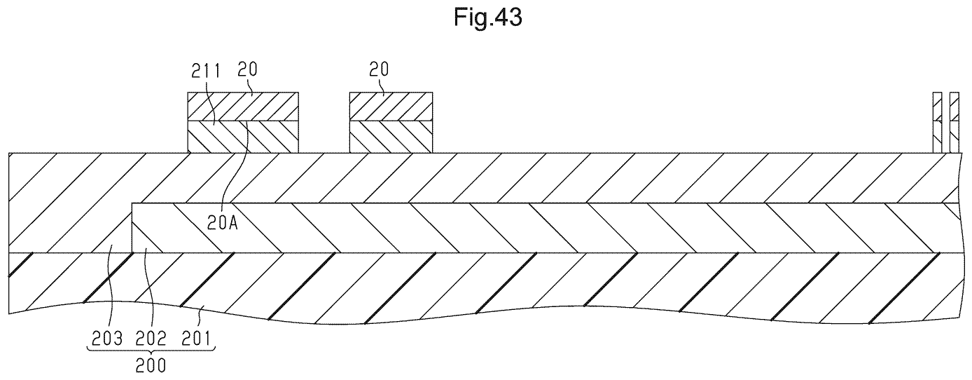

In the step illustrated in FIG. 43, the resist layer 210 illustrated in FIG. 42 is removed by an alkali delamination liquid in a manner similar to the step illustrated in FIG. 7.

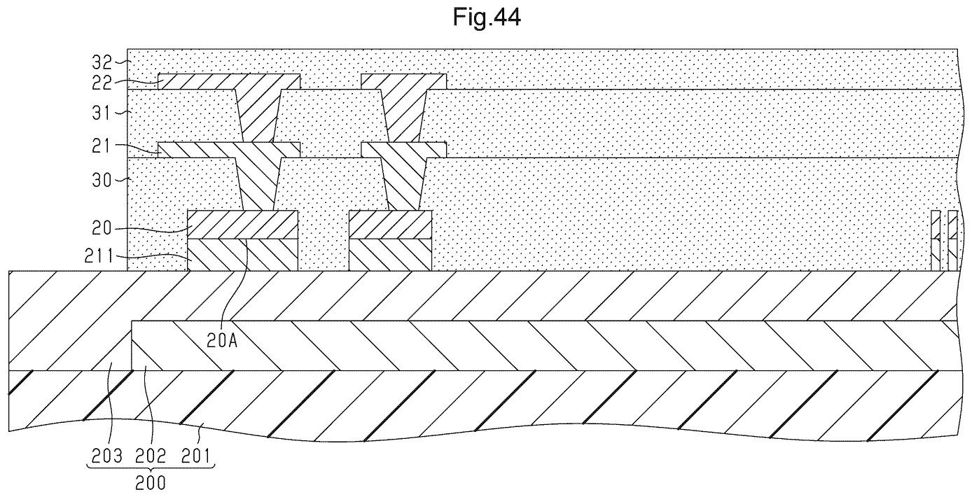

In the step illustrated in FIG. 44, the insulating layer 30, the wiring layer 21, the insulating layer 31, the wiring layer 22, and the insulating layer 32 are sequentially stacked on the upper surface of the metal film 203 in a manner similar to the steps illustrated in FIGS. 8 to 10.

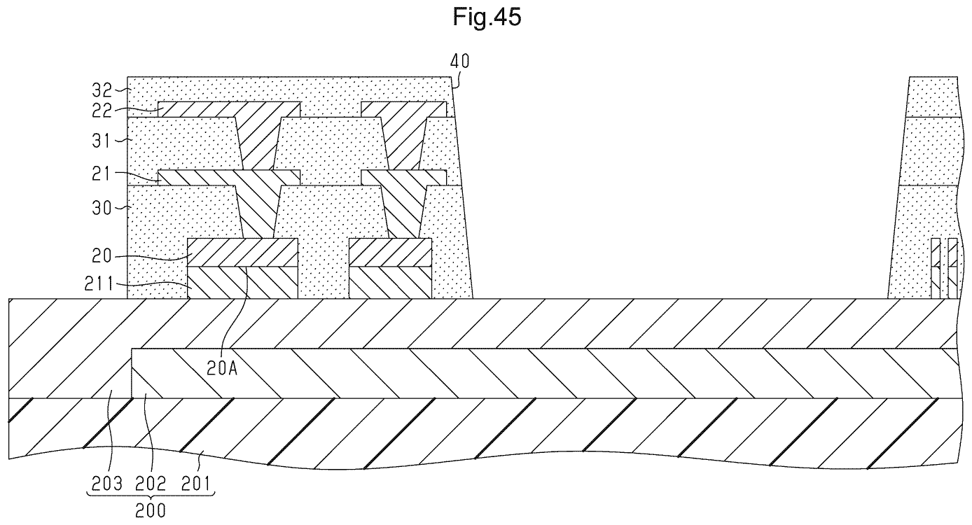

In the step illustrated in FIG. 45, the cavities 40, which are recessed from the upper surface of the insulating layer 32 toward the support 200, are formed to expose parts of the upper surface of the metal film 203 in a manner similar to the step illustrated in FIG. 12. The cavities 40 extend through the insulating layers 30, 31, and 32 in the thickness direction.

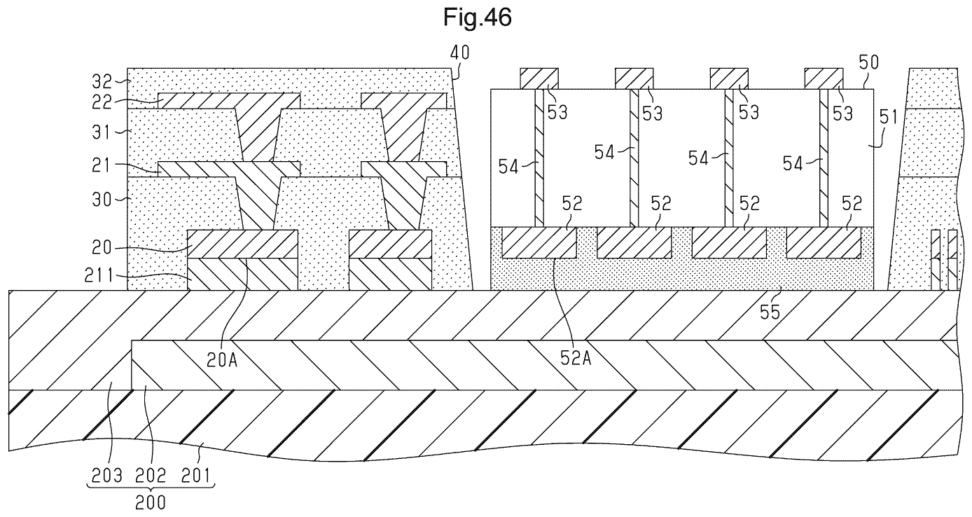

In the step illustrated in FIG. 46, a mounter is used to fix the electronic components 50 to the upper surface of the metal film 203 exposed from the cavities 40 with the insulating resin 55, which is adhesive, in a manner similar to the step of FIG. 13. In this state, the insulating resin 55 entirely covers the side surfaces of the first electrodes 52 and entirely covers the mounting surface 52A of each first electrode 52. In this step, the thickness of the insulating resin 55 from the mounting surface 52A of each first electrode 52 to the lower surface of the insulating resin 55 is adjusted so that the mounting surface 52A of each first electrode 52 is coplanar with the mounting surface 20A of the wiring layer 20.

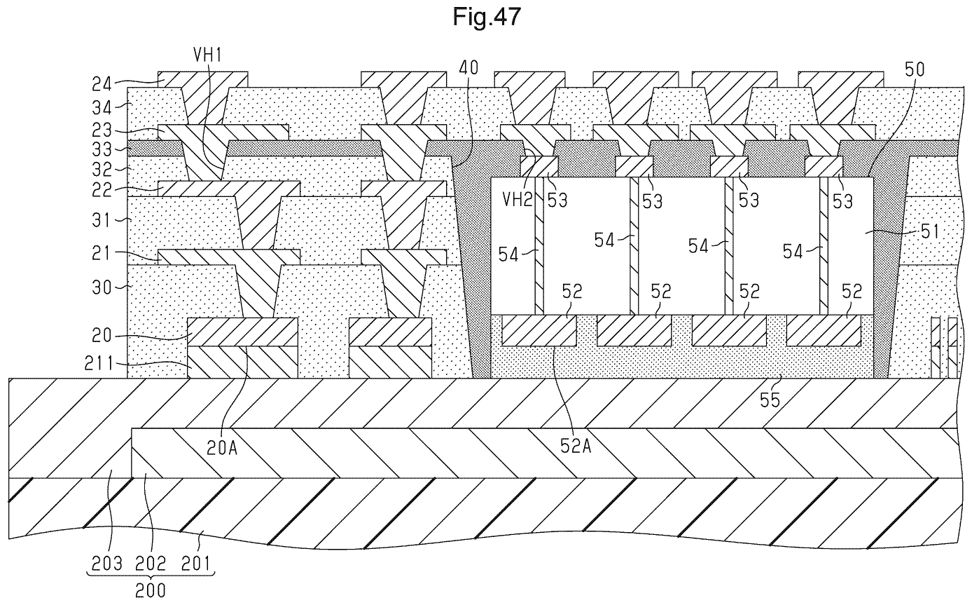

In the step illustrated in FIG. 47, the cavities 40 are filled with the insulating layer 33 that covers the upper surface of the insulating layer 32 in a manner similar to the step of FIG. 8. The insulating layer 33 entirely covers the side surfaces of the insulating resin 55.

Then, steps similar to the steps illustrated in FIGS. 8 to 10 are performed to sequentially form the wiring layer 23, the insulating layer 34, and the wiring layer 24 on the upper surface of the insulating layer 33.

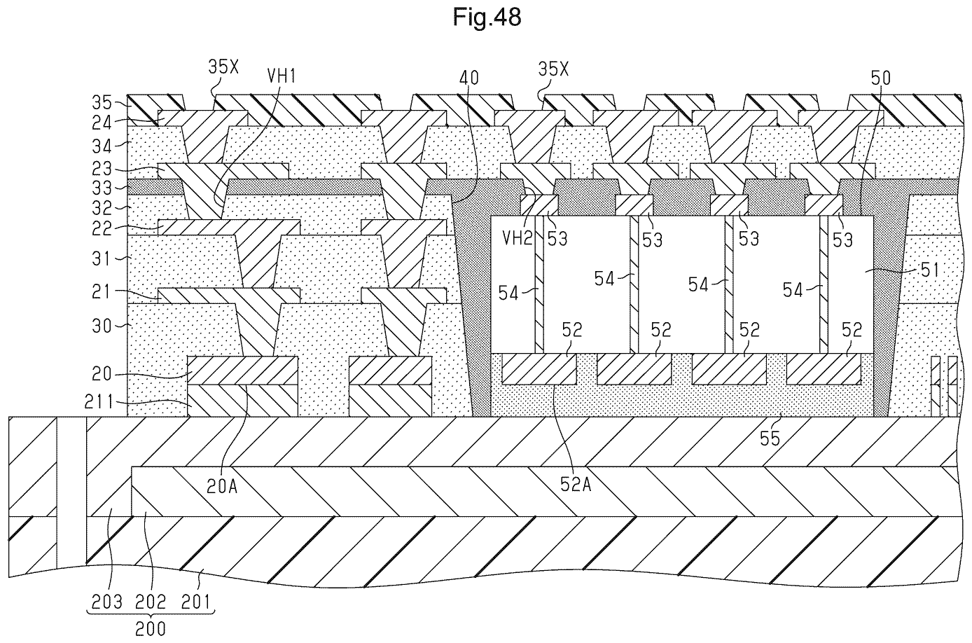

In the step illustrated in FIG. 48, the solder resist layer 35, which includes the openings 35X, is formed on the upper surface of the insulating layer 34 in a manner similar to the step of FIG. 18.

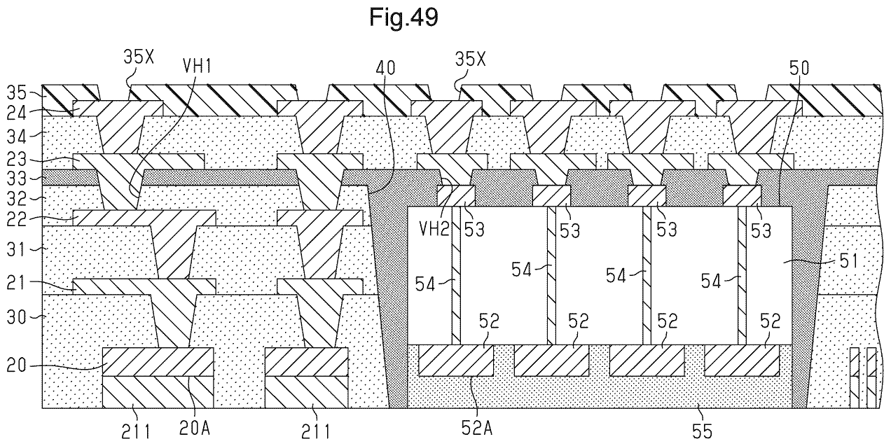

Then, a slicer or the like is used to cut away the peripheral region of the support 200. Further, steps similar to the steps of FIGS. 18 and 19 are performed to remove the support 200. This exposes the lower surfaces of the insulating layers 30 and 33, the lower surface of the insulating resin 55, and the lower surface of the metal layer 211, as illustrated in FIG. 49. In this state, the lower surfaces of the insulating layers 30 and 33 are flush with the lower surface of the insulating resin 55 and the lower surface of the metal layer 211.

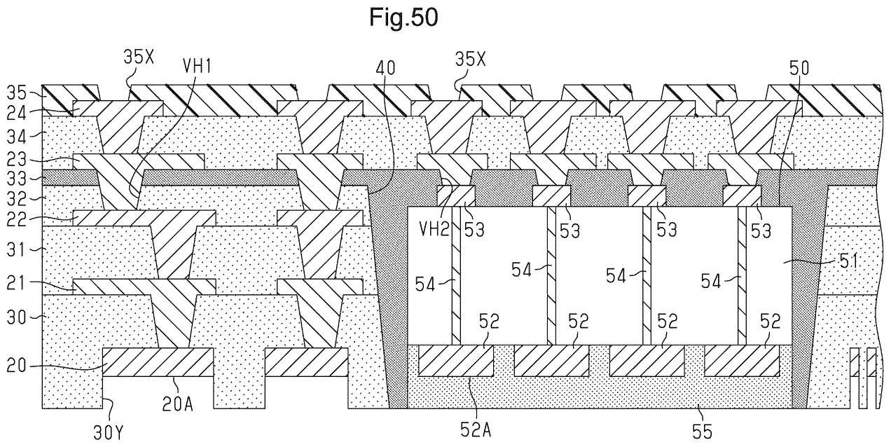

In the step illustrated in FIG. 50, the metal layer 211 is removed. This forms the openings 30Y, which entirely exposes the mounting surface 20A of the wiring layer 20, in the lower surface of the insulating layer 30. In this state, the inner wall of each opening 30Y is shaped in conformance with the corresponding side surface of the metal layer 211 (refer to FIG. 49).

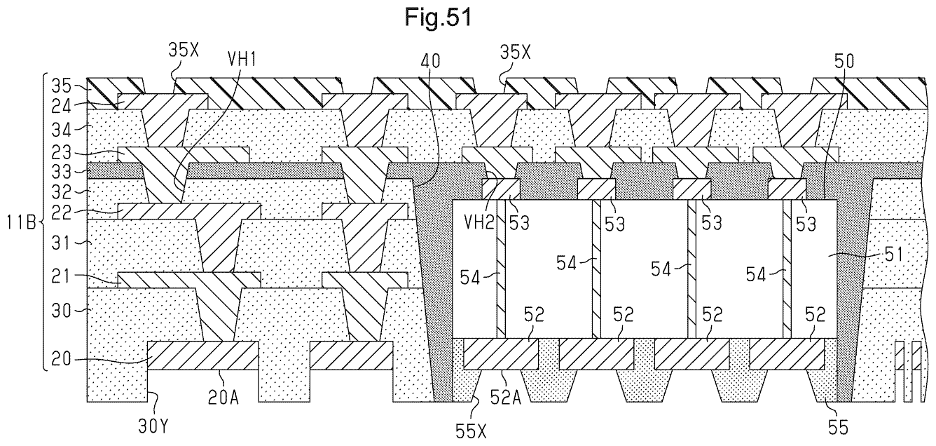

In the step illustrated in FIG. 51, the openings 55X are formed in the insulating resin 55 at given locations to expose a part of the mounting surface 52A of each first electrode 52. The openings 55X may be formed, for example, through laser processing using a CO₂ laser, a UV-YAG laser, or the like.

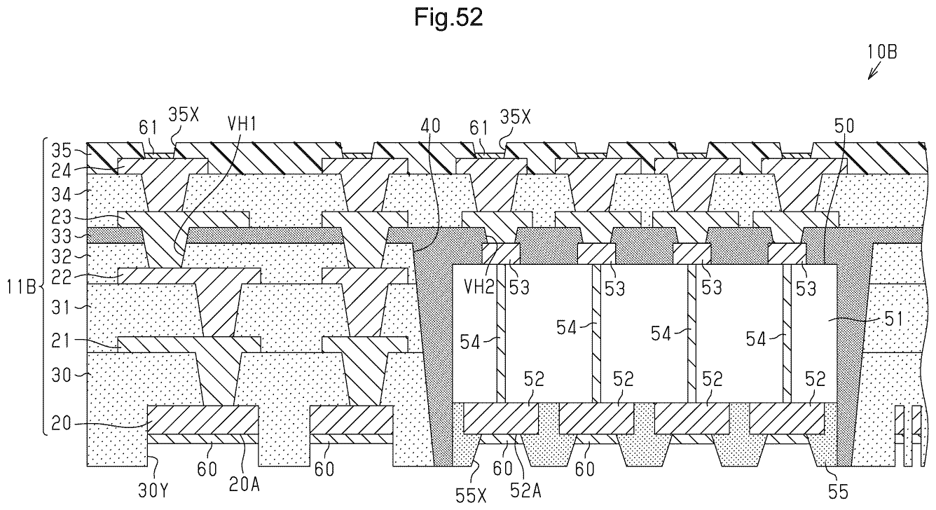

In the step illustrated in FIG. 52, the surface-processed layer 60 is formed on the mounting surfaces 20A and 52A that are exposed from the openings 30Y and 55X, and the surface-processed layer 61 is formed on the upper surface of the wiring layer 24 that is exposed from the openings 35X, in a manner similar to the step of FIG. 22. The wiring substrate 10B in accordance with the third embodiment is manufactured through the steps described above.

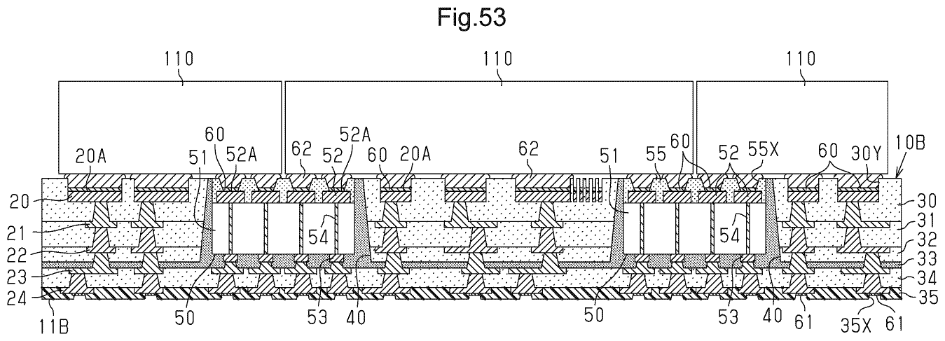

As illustrated in FIG. 53, the semiconductor chips 110 (three in the third embodiment) are mounted on the wiring substrate 10B. FIG. 53 illustrates the wiring substrate 10B in a state rotated 180° from the state of FIG. 52.

Each semiconductor chip 110 is flip-chip mounted on the wiring layer 20 and the first electrodes 52 of the wiring substrate 10B. Each semiconductor chip 110 is electrically connected to the wiring layer 20 and the first electrodes 52 by the bonding members 62 and the surface-processed layer 60. Each semiconductor chip 110 mounted on the wiring substrate 10B overlies the wiring layer 20 and the first electrodes 52. In this state, the mounting surface 20A (upper surface in FIG. 53) of the wiring layer 20 is coplanar with the mounting surface 52A (upper surface in FIG. 53) of each first electrode 52. This allows the semiconductor chips 110 to be readily mounted on the wiring layer 20 and the first electrodes 52 of the wiring substrate 10B.

The bonding members 62 are bonded to the surface-processed layer 60 that is formed on the wiring layer 20 and exposed from the openings 30Y. For example, the openings 30Y are filled with the bonding members 62. The bonding members 62 are bonded to the surface-processed layer 60 that is formed on the first electrodes 52 and exposed from the openings 55X. For example, the openings 55X are filled with the bonding members 62.

In the third embodiment, each opening 30Y is one example of a third opening, and each opening 55X is one example of a fourth opening.

### Advantages of the Third Embodiment

The third embodiment has advantages (1-1) and (1-2) of the first embodiment.

### MODIFIED EXAMPLES

The above embodiments may be modified as described below. The above-described embodiments and the modified examples described below may be combined as long as there is technical consistency.

The structures of the wiring substrates 10, 10A, and 10B in accordance with the above embodiments may be modified.

In the wiring substrates 10, 10A, and 10B in accordance with the above embodiments, there is no particular limitation to the number of wiring layers and insulating layers stacked on the upper surface of the cavity-capping insulating layer 33. For example, there may be only the wiring layer 23 formed on the upper surface of the insulating layer 33.

In each of the above embodiments, the solder resist layer 35 may be omitted.

In the wiring structures 11, 11A, and 11B of the above embodiments, the cavity formation insulating layer is formed by three layers; namely, the insulating layers 30, 31, and 32. Instead, the cavities may be formed by one insulating layer, two insulating layers, four insulating layers, or more.

There is no limitation to the number of the electronic components 50 incorporated in the wiring substrates 10, 10A, and 10B. For example, the wiring substrates 10, 10A, and 10B may each incorporate only one electronic component 50. For example, the wiring substrates 10, 10A, and 10B may each incorporate three or more electronic components 50.

In the wiring substrates 10, 10A, and 10B of the above embodiments, each cavity accommodates only one electronic component 50. This, however, is not a limitation. For example, more than one electronic component 50 may be disposed in each cavity 40.

In the above embodiments, the electronic component 50 incorporated in the wiring substrates 10, 10A, and 10B includes the through-electrodes 54. This, however, is not a limitation. For example, an electronic component that does not include the through-electrodes 54 may be incorporated in the wiring substrates 10, 10A, and 10B.

In the above embodiments, the electronic component 50 incorporated in the wiring substrates 10, 10A, and 10B includes two types of electrodes, namely, the first electrodes 52 and the second electrodes 53. This, however, is not a limitation. For example, an electrode including three or more types of electrodes may be incorporated in the wiring substrates 10, 10A, and 10B. For example, an electrode including only one type of electrode, that is, the first electrode 52, may be incorporated in the wiring substrates 10, 10A, and 10B.

The structure of the electronic component 50 incorporated in the wiring substrates 10, 10A, and 10B may be modified.

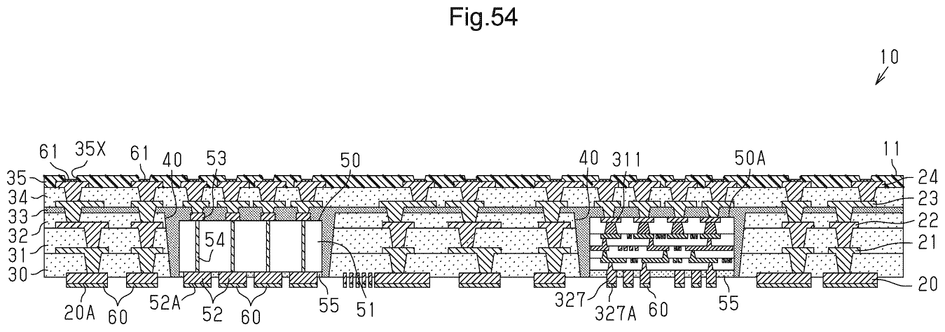

For example, as illustrated in FIG. 54, an electronic component 50A may be incorporated in the wiring substrate 10 instead of the electronic component 50. The electronic component 50A is, for example, an organic interposer.

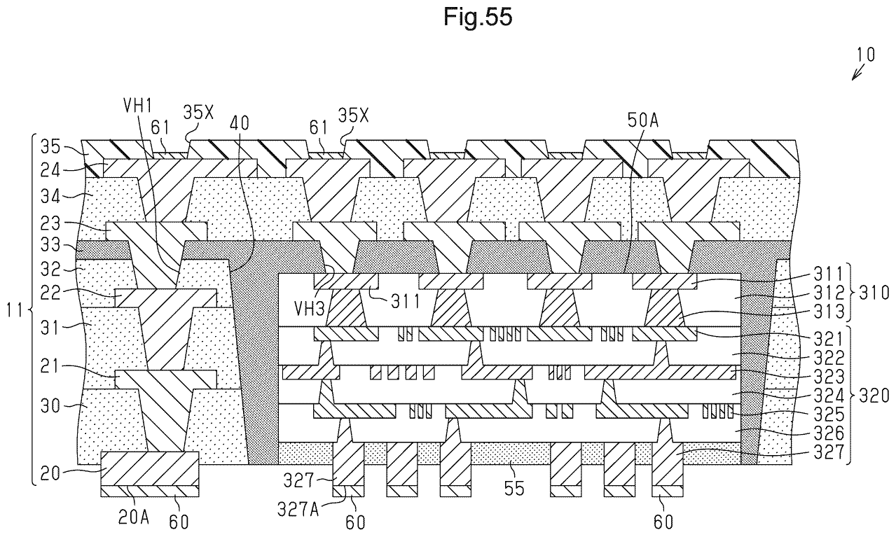

As illustrated in FIG. 55, the electronic component 50A includes, for example, a first wiring structure 310 and a second wiring structure 320 formed on the lower surface of the first wiring structure 310. The second wiring structure 320 is a micro-wiring structure including wiring layers having higher wiring density than the first wiring structure 310.

The first wiring structure 310 includes electrode pads 311, an insulating layer 312, and a wiring layer 313. The second wiring structure 320 includes a wiring layer 321, an insulating layer 322, a wiring layer 323, an insulating layer 324, a wiring layer 325, an insulating layer 326, and electrode pads 327. The material of the electrode pads 311 and 327 and the wiring layers 313, 321, 323, and 325 may be, for example, copper or a copper alloy.

The electrode pads 311 are embedded in the insulating layer 312. The upper surface of each electrode pad 311 is flush with, for example, the upper surface of the insulating layer 312.

The insulating layer 312 covers the lower surface and the side surface of each electrode pad 311 and exposes the lower surface of the wiring layer 313. The insulating layer 312 may, for example, be formed from a material of which the main component is a non-photosensitive thermosetting resin and may include a reinforcement member such as glass cloth. The insulating layer 312 has greater rigidity than the insulating layers 322, 324, and 326.

The insulating layers 322, 324, and 326 are formed from, for example, a material of which the main component is a photosensitive resin. The insulating layers 322, 324, and 326 may be formed from, for example, a photosensitive insulative resin of which the main component is a phenol resin or a polyimide resin. The insulating layers 322, 324, and 326 may include, for example, a filler such as silica or alumina.

The wiring layer 313 is via wiring embedded in the insulating layer 312. In this example, the wiring layer 313 extends through the insulating layer 312 in the thickness direction and fills through holes exposing a part of the lower surface of each electrode pad 311. The wiring layer 313 is electrically connected to the electrode pads 311. The lower surface of the wiring layer 313 is, for example, flush with the lower surface of the insulating layer 312.

The wiring layer 321 is formed on the lower surface of the insulating layer 312 and connected to the lower surface of the wiring layer 313. The wiring layer 321 is electrically connected to the wiring layer 313 but not integrated with the wiring layer 313.

The insulating layer 322 is formed on the lower surface of the insulating layer 312 and covers the wiring layer 321. The wiring layer 323 is formed on the lower surface of the insulating layer 322. The wiring layer 323 is electrically connected to the wiring layer 321 by via wiring that extends through the insulating layer 322 in the thickness direction. The insulating layer 324 is formed on the lower surface of the insulating layer 322 and covers the wiring layer 323. The wiring layer 325 is formed on the lower surface of the insulating layer 324. The wiring layer 325 is electrically connected to the wiring layer 323 by via wiring that extends through the insulating layer 324 in the thickness direction. The insulating layer 326 is formed on the lower surface of the insulating layer 324 and covers the wiring layer 325.

The electrode pads 327 are formed on the lower surface of the insulating layer 326. The electrode pads 327 are electrically connected to the wiring layer 325 by via wiring that extends through the insulating layer 326 in the thickness direction. The electrode pads 327 project downward beyond the lower surface of the insulating layer 326. The electrode pads 327 each include a mounting surface 327A (lower surface) on which an electronic component, such as the semiconductor chip 110 (refer to FIG. 3), is mounted. The mounting surface 327A of each electrode pad 327 is coplanar with the mounting surface 20A of the wiring layer 20.

A part of each electrode pad 327, namely, the upper portion of the electrode pad 327, is embedded in the insulating resin 55. In other words, the insulating resin 55 covers the upper portion of the side surface of each electrode pad 327.

The surface-processed layer 60 may be formed on the surface (mounting surface 327A and side surface, or only mounting surface 327A) of each electrode pad 327, when required. The surface-processed layer 60 of the present modified example covers only the mounting surface 327A of each electrode pad 327.

The insulating layer 33 of the present modified example includes through holes VH3 extending through the insulating layer 33 in the thickness direction at given locations and exposing a part of the upper surface of each electrode pad 311. The wiring layer 23 of the present modified example, for example, is electrically connected to the electrode pads 311 by a via wiring filling the through holes VH3.

In the present modified example, the electronic component 50A is one example of a first electronic component, the insulating layers 312, 322, 324, and 326 are one example of a main body, each electrode pad 327 is one example of a first electrode, and each electrode pad 311 is one example of a second electrode.

When incorporating the electronic component 50A, the mounting surface 327A of each electrode pad 327 is also coplanar with the mounting surface 20A of the wiring layer 20. This obtains the same advantages as the first embodiment.

The wiring substrates 10, 10A, and 10B in accordance with the above embodiments may be modified to incorporate only the electronic component 50A.

The structure of the substrate 70 in the above embodiments may be modified.

In the substrate 70 of the above embodiments, there is no particular limitation to the number of wiring layers and insulating layers stacked on the upper surface of the core substrate 71.

In the substrate 70 of the above embodiments, there is no particular limitation to the number of wiring layers and insulating layers stacked on the lower surface of the core substrate 71.

There is no limitation to the number of the electronic components 76 incorporated in the substrate 70 of the above embodiments. For example, the substrate 70 may incorporate only one electronic component 76. For example, the substrate 70 may incorporate three or more electronic components 76.

In the semiconductor device 1 in accordance with the above embodiments, there is no limitation to the number of the semiconductor chips 110 mounted on the wiring substrates 10, 10A, and 10B.

In the above embodiments, a structure corresponding to part of the wiring substrates 10, 10A, and 10B is formed on both upper and lower surfaces of the supports 200 and 220. This, however, is not a limitation. For example, a structure corresponding to part of the wiring substrates 10, 10A, and 10B may be formed on only one surface of the supports 200 and 220.

### CLAUSES

This disclosure further encompasses the following embodiments.
1. A method for manufacturing a wiring substrate, the method including:
preparing a support;
forming a first wiring layer on the support;
stacking an N number of insulating layers, including a first insulating layer covering the first wiring layer, on the support, where N is a natural number greater than or equal to 1;
forming a cavity, exposing a part of the support, in the N number of insulating layers;
fixing a first electronic component onto the support exposed from the cavity, the first electronic component including a first electrode;
forming a capping insulating layer that fills the cavity and covers the first electronic component; and
removing the support, in which
the first wiring layer includes a first mounting surface exposed from the first insulating layer,
the first electrode includes a second mounting surface exposed from the capping insulating layer,
the forming a first wiring layer includes forming the first wiring layer so that the first mounting surface contacts the support, and
the fixing a first electronic component includes fixing the first electronic component onto the support so that the second mounting surface is coplanar with the first mounting surface.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A wiring substrate of a coreless type, the wiring substrate comprising:
a first wiring layer;
an N number of insulating layers, including a first insulating layer that covers the first wiring layer, where N is a natural number greater than or equal to 1;
a cavity extending through the N number of insulating layers in a thickness direction:
a first electronic component disposed in the cavity and including a first electrode; and
a capping insulating layer filling the cavity and covering the first electronic component, wherein
the first wiring layer does not overlap the cavity in plan view,
the first wiring layer includes a first mounting surface exposed from the first insulating layer,
the first electrode includes a second mounting surface exposed from the capping insulating layer, and
the second mounting surface is coplanar with the first mounting surface.

2. The wiring substrate according to claim 1, wherein:
the first electronic component includes a main body, the first electrode, and an insulating resin, the first electrode projecting from a first surface of the main body in a first direction, and the insulating resin covering the first surface of the main body;
the insulating resin includes a second surface facing the first direction;
the first insulating layer includes a third surface facing the first direction; and
the second mounting surface is exposed from the second surface.

3. The wiring substrate according to claim 2, wherein;
the first insulating layer covers a part of a side surface of the first wiring layer;
the insulating resin covers a part of a side surface of the first electrode;
the first wiring layer projects beyond the third surface toward the first direction;
the first electrode projects beyond the second surface toward the first direction; and
the first mounting surface and the second mounting surface are located toward the first direction from the second surface.

4. The wiring substrate according to claim 2, wherein:
the first insulating layer entirely covers a side surface of the first wiring layer;
the insulating resin entirely covers a side surface of the first electrode;
the first mounting surface is flush with the third surface; and
the second mounting surface is flush with the second surface.

5. The wiring substrate according to claim 4, further comprising:
a solder resist layer formed on the second surface and the third surface,
wherein the solder resist layer includes a first opening that exposes a part of the first mounting surface and a second opening that exposes a part of the second mounting surface.

6. The wiring substrate according to claim 2, wherein:
the first insulating layer entirely covers a side surface of the first wiring layer;
the insulating resin entirely covers a side surface of the first electrode;
the third surface is coplanar with the second surface; and
the second surface and the third surface are located toward the first direction from the first mounting surface.

7. The wiring substrate according to claim 6, wherein:
the first insulating layer includes a third opening entirely exposing the first mounting surface;
the insulating resin includes a fourth opening exposing a part of the second mounting surface;
the third opening includes a wall surface extending perpendicular to the third surface; and
the fourth opening has an opening width that is reduced from the second surface toward the second mounting surface.

8. The wiring substrate according to claim 2, wherein the capping insulating layer includes a surface that is flush with the second surface and the third surface.

9. The wiring substrate according to claim 8, wherein the surface of the capping insulating layer, the second surface, the third surface, the first mounting surface, and the second mounting surface are flush with one another.

10. The wiring substrate according to claim 1, wherein:
the first electronic component includes a second electrode opposite the first electrode; and
the wiring substrate further comprises a second wiring layer located on the capping insulating layer and electrically connected to the second electrode.

11. A semiconductor device, comprising:
the wiring substrate according to claim 1; and
a second electronic component mounted on the first wiring layer and the first electrode of the wiring substrate,
wherein the second electronic component mounted on the wiring substrate overlies the first wiring layer and the first electrode.
